(19) United States
(12) Patent Application Publication
(10) Pub. No.: US 2026/0371846 A1
(43) Pub. Date: Nov. 19, 2026

(54) DISPLAY DEVICE AND ELECTRONIC DEVICE INCLUDING THE SAME

(71) Applicant: Samsung Display Co., Ltd., Yongin-si (KR)

(72) Inventor: Hyun Ae PARK, Yongin-si (KR)

(21) Appl. No.: 19/427,547

(22) Filed: Dec. 19, 2025

(30) Foreign Application Priority Data
May 15, 2025 (KR) 10-2025-0063050

(51) Int. Cl. H10K 59/121; H10K 59/131

(52) U.S. Cl. CPC H10K 59/1213; H10K 59/131

(57) ABSTRACT

A display device includes: a substrate including a display area having emission areas; a circuit layer on the substrate; and an element layer on the circuit layer, the element layer including light emitting elements, and the circuit layer including: light emitting pixel drivers transmitting a driving current to the light emitting elements; gate lines transmitting gate signals to the light emitting pixel drivers; a constant voltage line transmitting a constant voltage to the light emitting pixel drivers; a channel bias portion electrically connected to the constant voltage line; a first semiconductor layer on the substrate; a first interlayer insulating layer on the first semiconductor layer; and a second semiconductor layer on the first interlayer insulating layer and containing an oxide semiconductor material, wherein the second semiconductor layer comprises a non-design channel portion between some of the gate lines and the channel bias portion in a thickness direction.

### CROSS-REFERENCE TO RELATED APPLICATION

The present application claims priority to and the benefit of Korean Patent Application No. 10-2025-0063050, filed on May 15, 2025, in the Korean Intellectual Property Office, the entire disclosure of which is incorporated herein by reference.

### BACKGROUND

### 1. Technical Field

Aspects of some embodiments of the present disclosure relate to a display device and an electronic device including the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays images using light emitting elements, each including a light emitting layer containing an organic light emitting material. As described above, the organic light emitting display device implements image display using a self-light emitting element, and thus may have relatively superior performance in power consumption, response speed, luminous efficiency, luminance, and wide viewing angle compared to other display devices.

In the display device, a display surface from which light is emitted may include a display area at which images are displayed, and a non-display area around the display area. Emission areas emitting light with respective luminances and colors may be arranged in the display area.

The above information disclosed in this Background section is only for enhancement of understanding of the background and therefore the information discussed in this Background section does not necessarily constitute prior art.

### SUMMARY

A display device generally includes light emitting pixel drivers that transmit a driving current to light emitting elements.

Each of the light emitting pixel drivers may include two or more transistors. Channel portions of some of the two or more transistors may include an oxide semiconductor material. The oxide semiconductor material may be changed into an insulating material or a conductive material depending on the content of oxygen or hydrogen.

Accordingly, portions of the semiconductor layers including oxide semiconductor materials overlapping gate electrodes may become channel portions that maintain semiconductor characteristics, and some other portions may become electrodes or lines having conductivity.

However, depending on the arrangement of gate lines that each transmit a gate signal, an intersection area between the gate line and the semiconductor layer (hereinafter referred to as an "off-design channel portion") may additionally be generated separately from the channel portions of some transistors.

The off-design channel portion may cause malfunction of the light emitting pixel drivers, so that the display quality may relatively deteriorate.

In view of the foregoing, aspects of some embodiments of the present disclosure include a display device and an electronic device including the same, capable of relatively improving display quality because malfunction of light emitting pixel drivers due to a non-design channel portion may be prevented or reduced.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes a substrate comprising a display area in which emission areas are arranged; a circuit layer located on the substrate; and an element layer located on the circuit layer. According to some embodiments, the element layer comprises light emitting elements arranged in the emission areas. According to some embodiments, the circuit layer comprises light emitting pixel drivers each transmitting a driving current to the light emitting elements; gate lines transmitting gate signals to the light emitting pixel drivers; at least one constant voltage line transmitting at least one constant voltage to the light emitting pixel drivers; at least one channel bias portion electrically connected to the at least one constant voltage line; a first semiconductor layer located on the substrate; a first interlayer insulating layer located on the first semiconductor layer; and a second semiconductor layer located on the first interlayer insulating layer and containing an oxide semiconductor material. According to some embodiments, the second semiconductor layer comprises at least one non-design channel portion located between some of the gate lines and the at least one channel bias portion in a thickness direction of the substrate.

According to some embodiments, each of the light emitting pixel drivers comprises a first transistor generating the driving current; a second transistor electrically connected between a data line transmitting a data signal and a gate electrode of the first transistor; a third transistor electrically connected between a reference voltage line transmitting a reference voltage and the gate electrode of the first transistor; a fourth transistor electrically connected between an initialization voltage line transmitting an initialization voltage and one of the light emitting elements; a fifth transistor electrically connected between a first power line transmitting first power and a first electrode portion of the first transistor; and a sixth transistor electrically connected between the one light emitting element and a second electrode portion of the first transistor. According to some embodiments, the first transistor is located in the second semiconductor layer and comprises a channel portion overlapping the gate electrode of the first transistor. According to some embodiments, the first electrode portion of the first transistor is located in the second semiconductor layer and connected to one side of the channel portion of the first transistor. According to some embodiments, the second electrode portion of the first transistor is located in the second semiconductor layer and connected to the other side of the channel portion of the first transistor. According to some embodiments, the at least one constant voltage line comprises at least one of the first power line, the reference voltage line, or the initialization voltage line.

According to some embodiments, a gate electrode of the fifth transistor is electrically connected to a first emission control line transmitting a first emission control signal. According to some embodiments, a gate electrode of the sixth transistor is electrically connected to a second emission control line transmitting a second emission control signal different from the first emission control signal. According to some embodiments, the sixth transistor comprises a channel portion located in the second semiconductor layer and overlapping the gate electrode of the sixth transistor. According to some embodiments, a first electrode portion of the sixth transistor is located in the second semiconductor layer, connected to one side of the channel portion of the sixth transistor, and electrically connected to the second electrode portion of the first transistor. According to some embodiments, a second electrode portion of the sixth transistor is located in the second semiconductor layer, connected to the other side of the channel portion of the sixth transistor, and electrically connected to the one light emitting element.

According to some embodiments, the circuit layer further comprises a first gate insulating layer covering the first semiconductor layer; a first gate conductive layer located on the first gate insulating layer; a second gate insulating layer covering the first gate conductive layer; a second gate conductive layer located on the second gate insulating layer; a third gate insulating layer covering the second semiconductor layer; a third gate conductive layer located on the third gate insulating layer; and a first source-drain conductive layer located on the second interlayer insulating layer. The first interlayer insulating layer covers the second gate conductive layer. According to some embodiments, the second interlayer insulating layer covers the third gate conductive layer.

According to some embodiments, the first emission control line is located in the first gate conductive layer. According to some embodiments, the first power line comprises a power sub-line located in the first gate conductive layer and extending in a first direction; and a power main line located in the first source-drain conductive layer and extending in the first direction.

According to some embodiments, the gate lines comprise the first emission control line and the second emission control line. Each of the first emission control line and the second emission control line extends in the first direction. According to some embodiments, the first emission control line is located between the first transistor and the second emission control line in a second direction intersecting the first direction. According to some embodiments, a portion of the power main line extends in the first direction between the first emission control line and the second emission control line in the second direction. According to some embodiments, the at least one channel bias portion comprises a first channel bias portion protruding from the power main line and overlapping a portion of the first emission control line. According to some embodiments, the at least one non-design channel portion comprises a first non-design channel portion located between a portion of the first emission control line and the first channel bias portion in the thickness direction of the substrate.

According to some embodiments, each of the light emitting pixel drivers further comprises a first capacitor electrically connected between the gate electrode of the first transistor and the second electrode portion of the first transistor; and a second capacitor electrically connected between the first power line and the second electrode portion of the first transistor.

According to some embodiments, each of the light emitting pixel drivers further comprises a first capacitor electrically connected between the gate electrode of the first transistor and the second electrode portion of the first transistor; a second capacitor electrically connected to the second electrode portion of the first transistor; and a seventh transistor electrically connected between the second capacitor and the reference voltage line. According to some embodiments, the seventh transistor is located in the second semiconductor layer and comprises a channel portion overlapping a gate electrode of the seventh transistor. According to some embodiments, a first electrode portion and a second electrode portion of the seventh transistor are located in the second semiconductor layer.

According to some embodiments, a gate electrode of the third transistor is electrically connected to a reset control line transmitting a reset control signal. According to some embodiments, the gate electrode of the seventh transistor is electrically connected to a gate control line transmitting a gate control signal. According to some embodiments, each of the reference voltage line, the reset control line, and the gate control line extends in a first direction. According to some embodiments, the reset control line is located between the reference voltage line and the gate control line in a second direction intersecting the first direction.

According to some embodiments, the circuit layer further comprises a first gate insulating layer covering the first semiconductor layer; a first gate conductive layer located on the first gate insulating layer; a second gate insulating layer covering the first gate conductive layer; a second gate conductive layer located on the second gate insulating layer; a third gate insulating layer covering the second semiconductor layer; a third gate conductive layer located on the third gate insulating layer; and a first source-drain conductive layer located on the second interlayer insulating layer. According to some embodiments, the reference voltage line comprises a reference voltage sub-line located in the first semiconductor layer and extending in the first direction; and a reference voltage main line located in the first source-drain conductive layer, extending in the first direction, and overlapping the reference voltage sub-line.

According to some embodiments, the gate lines further comprise the reset control line and the gate control line. According to some embodiments, the gate control line is located in the third gate conductive layer. According to some embodiments, the reset control line is located in the first source-drain conductive layer and extends in the first direction. According to some embodiments, the at least one channel bias portion comprises a second channel bias portion protruding from the reference voltage sub-line and overlapping a portion of the reset control line. According to some embodiments, the at least one non-design channel portion comprises a second non-design channel portion located between a portion of the reset control line and the second channel bias portion in the thickness direction of the substrate.

According to some embodiments, a remaining portion of the first semiconductor layer, excluding a portion intersecting the first emission control line, has conductivity.

According to some embodiments of the present disclosure, an electronic device includes a display device displaying an image; a memory storing an application; a processor executing the application and transmitting an image data signal and an input control signal to the display device; and a power module transmitting power to the display device. According to some embodiments, the display device comprises a substrate comprising a display area in which emission areas are arranged; a circuit layer located on the substrate; and an element layer located on the circuit layer. According to some embodiments, the element layer comprises light emitting elements arranged in the emission areas. According to some embodiments, the circuit layer comprises light emitting pixel drivers each transmitting a driving current to the light emitting elements; a first semiconductor layer located on the substrate; a first interlayer insulating layer located on the first semiconductor layer; and a second semiconductor layer located on the first interlayer insulating layer and containing an oxide semiconductor material. According to some embodiments, each of the light emitting pixel drivers comprises a first transistor generating the driving current; a second transistor electrically connected between a data line transmitting a data signal and a gate electrode of the first transistor; a third transistor electrically connected between a reference voltage line transmitting a reference voltage and the gate electrode of the first transistor; a fourth transistor electrically connected between an initialization voltage line transmitting an initialization voltage and one of the light emitting elements; a fifth transistor electrically connected between a first power line transmitting first power and a first electrode portion of the first transistor; and a sixth transistor electrically connected between the one light emitting element and a second electrode portion of the first transistor. According to some embodiments, the first transistor is located in the second semiconductor layer and comprises a channel portion overlapping the gate electrode of the first transistor. According to some embodiments, the first electrode portion of the first transistor is located in the second semiconductor layer and connected to one side of the channel portion of the first transistor. According to some embodiments, the second electrode portion of the first transistor is located in the second semiconductor layer and connected to the other side of the channel portion of the first transistor. According to some embodiments, a gate electrode of the fifth transistor is electrically connected to a first emission control line transmitting a first emission control signal. According to some embodiments, a gate electrode of the sixth transistor is electrically connected to a second emission control line transmitting a second emission control signal different from the first emission control signal. According to some embodiments, the sixth transistor comprises a channel portion located in the second semiconductor layer and overlapping the gate electrode of the sixth transistor. According to some embodiments, a first electrode portion of the sixth transistor is located in the second semiconductor layer, connected to one side of the channel portion of the sixth transistor, and electrically connected to the second electrode portion of the first transistor. According to some embodiments, a second electrode portion of the sixth transistor is located in the second semiconductor layer, connected to the other side of the channel portion of the sixth transistor, and electrically connected to the one light emitting element. According to some embodiments, the second semiconductor layer comprises a first non-design channel portion overlapping a portion of the first emission control line and the first channel bias portion in a thickness direction of the substrate. According to some embodiments, the first channel bias portion is electrically connected to the first power line.

According to some embodiments, the circuit layer further comprises a first gate insulating layer covering the first semiconductor layer; a first gate conductive layer located on the first gate insulating layer; a second gate insulating layer covering the first gate conductive layer; a second gate conductive layer located on the second gate insulating layer; a third gate insulating layer covering the second semiconductor layer; a third gate conductive layer located on the third gate insulating layer; and a first source-drain conductive layer located on the second interlayer insulating layer. According to some embodiments, the first interlayer insulating layer covers the second gate conductive layer. According to some embodiments, the second interlayer insulating layer covers the third gate conductive layer. According to some embodiments, the first emission control line is located in the first gate conductive layer. According to some embodiments, the gate electrode of the fifth transistor is a portion of the first emission control line. According to some embodiments, the second emission control line is located in the third gate conductive layer. According to some embodiments, the gate electrode of the sixth transistor is a portion of the second emission control line.

According to some embodiments, each of the first emission control line and the second emission control line extends in a first direction. According to some embodiments, the first emission control line is located between the first transistor and the second emission control line in a second direction intersecting the first direction.

According to some embodiments, the first power line comprises a power sub-line located in the first gate conductive layer and extending in the first direction; and a power main line located in the first source-drain conductive layer and extending in the first direction. According to some embodiments, the first emission control line is located between the power sub-line and the power main line in the second direction. According to some embodiments, the first channel bias portion protrudes from the power main line.

According to some embodiments, each of the light emitting pixel drivers further comprises a first capacitor electrically connected between the gate electrode of the first transistor and the second electrode portion of the first transistor; a second capacitor electrically connected to the second electrode portion of the first transistor; and a seventh transistor electrically connected between the second capacitor and the reference voltage line. According to some embodiments, the seventh transistor is located in the second semiconductor layer and comprises a channel portion overlapping a gate electrode of the seventh transistor. According to some embodiments, a first electrode portion and a second electrode portion of the seventh transistor are located in the second semiconductor layer.

According to some embodiments, a gate electrode of the third transistor is electrically connected to a reset control line transmitting a reset control signal. According to some embodiments, the gate electrode of the seventh transistor is electrically connected to a gate control line transmitting a gate control signal. According to some embodiments, each of the reference voltage line, the reset control line, and the gate control line extends in a first direction. According to some embodiments, the reset control line is located between the reference voltage line and the gate control line in a second direction intersecting the first direction. According to some embodiments, the second semiconductor layer further comprises a second non-design channel portion overlapping a portion of the reset control line and the second channel bias portion in the thickness direction of the substrate. According to some embodiments, the second channel bias portion is electrically connected to the reference voltage line.

According to some embodiments, the reference voltage line comprises a reference voltage sub-line located in the first semiconductor layer and extending in the first direction; and a reference voltage main line located in the first source-drain conductive layer, extending in the first direction, and overlapping the reference voltage sub-line. According to some embodiments, the reset control line is located in the first source-drain conductive layer and extends in the first direction. he second channel bias portion protrudes from the reference voltage sub-line.

According to some embodiments, a remaining portion of the first semiconductor layer, excluding a portion intersecting the first emission control line, has conductivity.

According to some embodiments, a circuit layer of the display device may include a first semiconductor layer located on a substrate, a first interlayer insulating layer located on the first semiconductor layer, a second semiconductor layer located on the first interlayer insulating layer and including an oxide semiconductor material, and a channel bias portion overlapping a portion of the second semiconductor layer.

According to some embodiments, the channel bias portion may be electrically connected to at least one constant voltage line that transmits a constant voltage.

According to some embodiments, each of the light emitting pixel drivers may include a first transistor, a second transistor located between a data line and a gate electrode of the first transistor, a third transistor located between a reference voltage line and the gate electrode of the first transistor, a fourth transistor located between an initialization voltage line and one light emitting element, a fifth transistor located between a first power line and the first transistor, and a sixth transistor located between one light emitting element and the first transistor.

According to some embodiments, the gate electrode of the fifth transistor may be electrically connected to a first emission control line that transmits a first emission control signal.

According to some embodiments, the gate electrode of the sixth transistor may be electrically connected to a second emission control line that transmits a second emission control signal.

According to some embodiments, the channel portion of the sixth transistor may be located in the second semiconductor layer.

According to some embodiments, the second semiconductor layer may include a first non-design channel portion located between the first transistor and the sixth transistor and intersecting the first emission control line. According to some embodiments, the channel bias portion may include a first channel bias portion overlapping the first non-design channel portion.

According to some embodiments, the first power line may include a power main line adjacent to the first emission control line.

According to some embodiments, the first channel bias portion may protrude from the power main line.

In this way, although the first non-design channel portion may maintain semiconductor characteristics, it may be maintained in a turned-on state by first power applied to the first channel bias portion, regardless of the first emission control signal.

That is, because the first non-design channel portion is not turned off by the first emission control signal, malfunction of the light emitting pixel driver due to the on-off operation of the first non-design channel portion may be prevented or reduced. Accordingly, the display quality of the display device may be relatively improved.

According to some embodiments, each of the light emitting pixel drivers may further include a first capacitor electrically connected between the gate electrode of the first transistor and the second electrode portion of the first transistor, and a second capacitor and a seventh transistor connected in series between the second electrode portion of the first transistor and the reference voltage line.

According to some embodiments, the gate electrode of the third transistor may be electrically connected to a reset control line that transmits a reset control signal.

According to some embodiments, the gate electrode of the seventh transistor may be electrically connected to a gate control line that transmits a gate control signal.

According to some embodiments, the second semiconductor layer may include a second non-design channel portion located between the reference voltage line and the seventh transistor and intersecting the reset control line. According to some embodiments, the channel bias portion may include a second channel bias portion overlapping the second non-design channel portion.

According to some embodiments, the circuit layer may further include a first source-drain conductive layer located on the second interlayer insulating layer.

According to some embodiments, the reference voltage line may include a reference voltage sub-line adjacent to the reset control line and located in the first semiconductor layer, and a reference voltage main line located in the first source-drain conductive layer.

According to some embodiments, the reset control line may be located in the first source-drain conductive layer.

According to some embodiments, the second channel bias portion may protrude from the reference voltage sub-line.

In this way, although the second non-design channel portion maintains semiconductor characteristics, it may be maintained in a turned-on state by the reference voltage applied to the second channel bias portion, regardless of the reset control signal.

That is, because the second non-design channel portion is not turned off by the reset control signal, malfunction of the light emitting pixel driver due to the on-off operation of the second non-design channel portion may be prevented or reduced. Therefore, the display quality of the display device may be relatively improved.

It should be noted that the characteristics of embodiments according to the present disclosure are not limited to those described above and other characteristics of embodiments according to the present disclosure will be more apparent to those skilled in the art from the following descriptions.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view showing an electronic device according to some embodiments;

FIG. 2 is an exploded perspective view of the electronic device shown in FIG. 1;

FIG. 3 is a plan view illustrating the display device of FIG. 2;

FIG. 4 is a cross-sectional view taken along the line A-A' of FIG. 3;

FIG. 5 is a schematic diagram showing part B of FIG. 3;

FIG. 6 is a block diagram showing the display device of FIG. 2;

FIG. 7 is an equivalent circuit diagram showing the light emitting pixel driver of FIG. 6 according to some embodiments;

FIG. 8 is a cross-sectional view showing the first transistor, the fifth transistor, the sixth transistor, and the light emitting element of FIG. 7;

FIGS. 9 and 10 are plan views illustrating a first transistor, a fifth transistor, a sixth transistor, and a first channel bias portion according to some embodiments as illustrated in FIG. 7;

FIG. 11 is a cross-sectional view taken along the line C-C' of FIG. 10;

FIG. 12 is an equivalent circuit diagram showing the light emitting pixel driver of FIG. 6 according to some embodiments;

FIGS. 13, 14, 15, and 16 are plan views illustrating a first transistor, a second transistor, a third transistor, a seventh transistor, and a second channel bias portion according to some embodiments as illustrated in FIG. 12;

FIG. 17 is a cross-sectional view taken along the line D-D' of FIG. 15;

FIG. 18 is a block diagram of an electronic device according to some embodiments; and

FIG. 19 is schematic views of electronic devices according to some embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being "on" another layer or substrate, it can be directly on the other layer or substrate, or intervening layers may also be present. In contrast, when an element is referred to as being "directly on" another element, there may be no intervening elements present.

Further, the phrase "in a plan view" means when an object portion is viewed from above, and the phrase "in a schematic cross-sectional view" means when a schematic cross-section taken by vertically cutting an object portion is viewed from the side. The terms "overlap" or "overlapped" mean that a first object may be above or below or to a side of a second object, and vice versa. Additionally, the term "overlap" may include layer, stack, face or facing, extending over, covering, or partly covering or any other suitable term as would be appreciated and understood by those of ordinary skill in the art. The expression "not overlap" may include meaning such as "apart from" or "set aside from" or "offset from" and any other suitable equivalents as would be appreciated and understood by those of ordinary skill in the art. The terms "face" and "facing" may mean that a first object may directly or indirectly oppose a second object. In a case in which a third object intervenes between a first and second object, the first and second objects may be understood as being indirectly opposed to one another, although still facing each other.

The spatially relative terms "below," "beneath," "lower," "above," "upper," or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned "below" or "beneath" another device may be placed "above" another device. Accordingly, the illustrative term "below" may include both the lower and upper positions. The device may also be oriented in other directions and thus the spatially relative terms may be interpreted differently depending on the orientations.

When an element is referred to as being "connected" or "coupled" to another element, the element may be "directly connected" or "directly coupled" to another element, or "electrically connected" or "electrically coupled" to another element with one or more intervening elements interposed therebetween. It will be further understood that when the terms "comprises," "comprising," "has," "have," "having," "includes" and/or "including" are used, they may specify the presence of stated features, integers, steps, operations, elements and/or components, but do not preclude the presence or addition of other features, integers, steps, operations, elements, components, and/or any combination thereof.

It will be understood that, although the terms "first," "second," "third," or the like may be used herein to describe various elements, these elements should not be limited by these terms. These terms are used to distinguish one element from another element or for the convenience of description and explanation thereof. For example, when "a first element" is discussed in the description, it may be termed "a second element" or "a third element," and "a second element" and "a third element" may be termed in a similar manner without departing from the teachings herein.

The terms "about" or "approximately" as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, "about" may mean within one or more standard deviations, or within ± 30%, 20%, 10%, 5% of the stated value.

In the specification and the claims, the term "and/or" is intended to include any combination of the terms "and" and "or" for the purpose of its meaning and interpretation. For example, "A and/or B" may be understood to mean "A, B, or A and B." The terms "and" and "or" may be used in the conjunctive or disjunctive sense and may be understood to be equivalent to "and/or." In the specification and the claims, the phrase "at least one of" is intended to include the meaning of "at least one selected from the group of" for the purpose of its meaning and interpretation. For example, "at least one of A and B" may be understood to mean "A, B, or A and B."

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

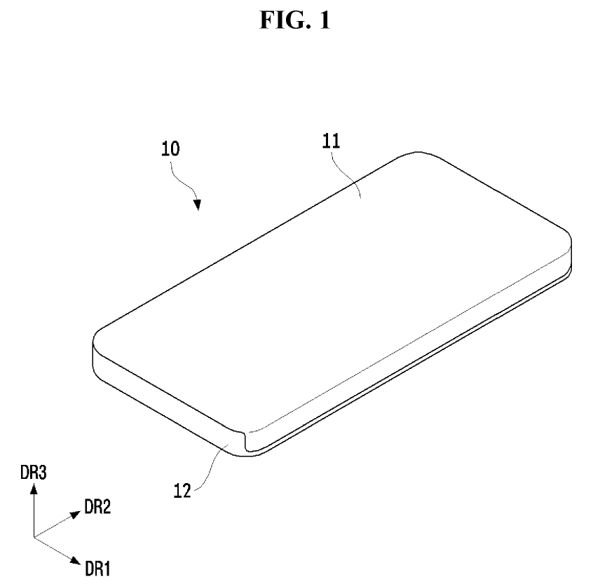

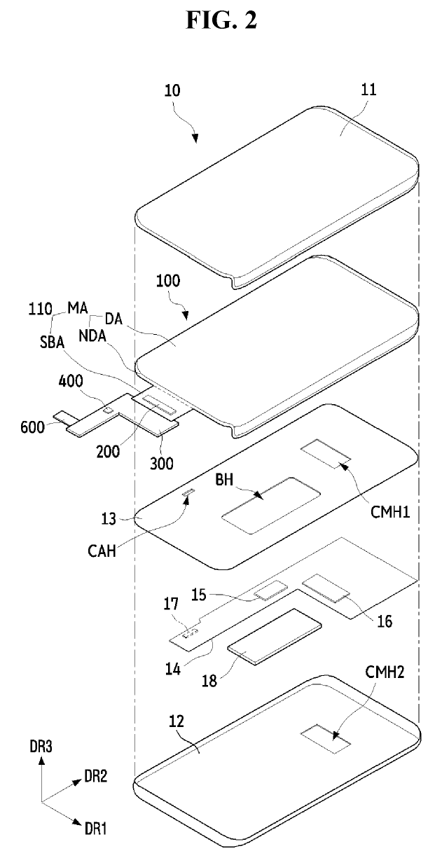

FIG. 1 is a perspective view showing an electronic device according to some embodiments. FIG. 2 is an exploded perspective view of the electronic device shown in FIG. 1.

Referring to FIG. 1, an electronic device 10 according to some embodiments is a device having a function of displaying an image in a display area. The electronic device 10 may provide portability. For example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 10 according to some embodiments is not limited to a portable electronic device, and may be a large-sized device such as a television, a laptop computer, a monitor, a billboard, and an Internet-of-Things (IoT) device.

The electronic device 10 according to some embodiments may include a cover window 11 and a lower cover 12, which are provided as a housing to protect a display device 100 (see FIG. 2).

Referring to FIG. 2, the electronic device 10 may further include the display device 100, a bracket 13, and a main circuit board 14, which are accommodated between the cover window 11 and the lower cover 12.

The display device 100 may include a main region MA including a display area DA where an image is displayed and a non-display area NDA around the display area DA, and a sub-region SBA protruding from one side of the main region MA.

The display device 100 may further include a display driving circuit 200 located in the sub-region SBA, a display circuit board 300 bonded to one side of the sub-region SBA, a touch driving circuit 400 mounted on the display circuit board 300, and a cable 600 extending from one side of the display circuit board 300.

In the present specification, a first direction DR1 may be a direction parallel to a short side of the electronic device 10 in a plan view, that is, a horizontal direction of the electronic device 10. A second direction DR2 may be a direction parallel to a long side of the electronic device 10 in a plan view, that is, a vertical direction of the electronic device 10. A third direction DR3 may be a thickness direction of the electronic device 10.

The electronic device 10 may have a shape close to a rectangular shape in a plan view. For example, the electronic device 10 may have a rectangular shape, in a plan view, having a short side in the first direction DR1 and a long side in the second direction DR2. A corner where the short side in the first direction DR1 and the long side in the second direction DR2 meet may be right-angled or rounded with a selected curvature. The planar shape of the electronic device 10 is not limited to the rectangular shape, and may be formed in another polygonal shape, a circular shape, an elliptical shape, or an irregular shape.

The cover window 11 may be located on the display device 100 to cover the top surface of the display device 100. The cover window 11 may serve to protect the top surface of the display device 100.

The cover window 11 may include a light transmitting portion that is transparent and a light blocking portion that is opaque.

The light transmitting portion may overlap the display area DA of the display device 100 in the third direction DR3, and the light blocking portion may overlap the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion, and the right surface portion thereof may extend from the right side of the top surface portion.

Each of the top, left, and right surface portions of the cover window 11 may include the light transmitting portion and the light blocking portion.

The light transmitting portion of the cover window 11 may be located on most of each of the top, left, and right surface portions of the cover window 11.

The light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be located below the cover window 11.

That is, the cover window 11 may be located on the display device 100.

The display device 100 may include a top surface portion facing the top surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

The display device 100 may include the main region MA serving as a display surface and the sub-region SBA protruding from at least a part of one side of the main region MA.

The main region MA may include the display area DA displaying images and the non-display area NDA that is a peripheral area (e.g., surrounding or outside a footprint) of the display area DA where images are not displayed.

The display area DA may be located in most of the main region MA. The display area DA may be located at the center of the main region MA.

In other words, each of the top, left, and right surface portions of the display device 100 may include the display area DA and the non-display area NDA.

The display area DA may be located on most of each of the top, left, and right surface portions of the display device 100.

The non-display area NDA may be located outside (e.g., in a periphery or outside a footprint of) the display area DA. The non-display area NDA may be an edge area of the main region MA.

The non-display area NDA may be located at the upper edge and lower edge of the top surface portion of the display device 100, the upper edge, left edge, and lower edge of the left surface portion of the display device 100, and the upper edge, right edge, and lower edge of the right surface portion of the display device 100.

The sub-region SBA may protrude from one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but embodiments according to the present disclosure are not limited thereto.

Because a part of the sub-region SBA is transformed to be bent, another part of the sub-region SBA may overlap the main region MA in the third direction DR3.

The display driving circuit 200 may be mounted on the sub-region SBA, and the display circuit board 300 may be attached to the sub-region SBA.

One end of the display circuit board 300 may be attached to pads located at the lower edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

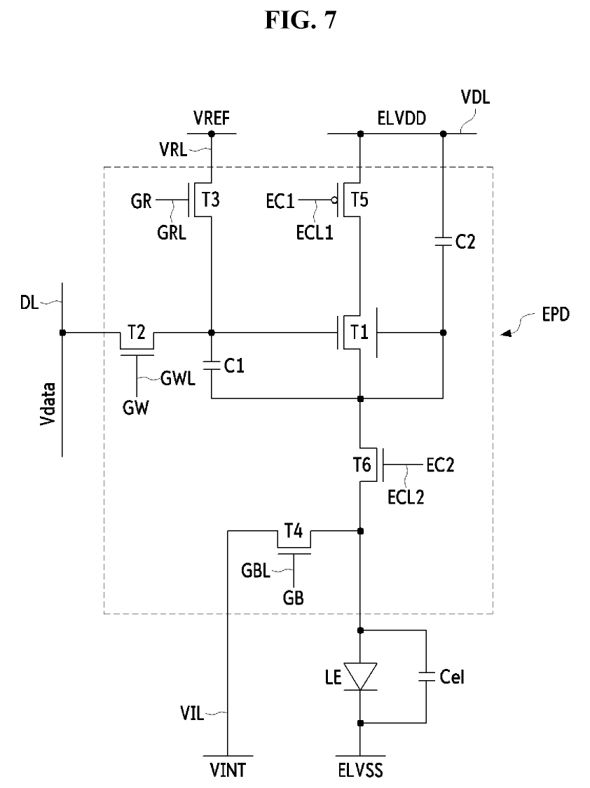

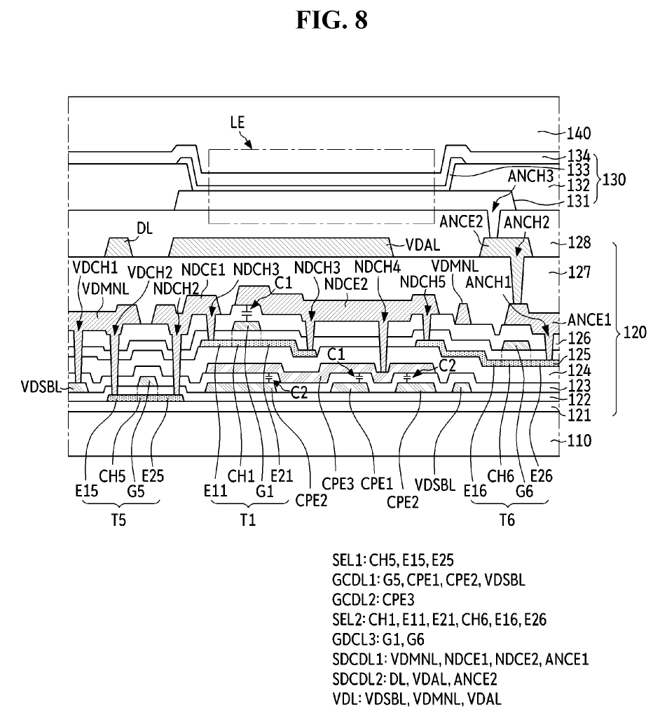

Based on control signals, power and voltages supplied through the display circuit board 300, the display driving circuit 200 may transmit a data signal Vdata (see FIG. 8) of each of light emitting pixel drivers EPD (see FIG. 7) of the display area DA to data lines DL (see FIG. 7).

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and embodiments according to the present disclosure are not limited thereto. For example, the display driving circuit 200 may be mounted on the display circuit board 300.

According to some embodiments, the touch driving circuit 400 may be further mounted on the sub-region SBA of the display device 100.

Alternatively, as shown in FIG. 2, the touch driving circuit 400 may be mounted on the display circuit board 300.

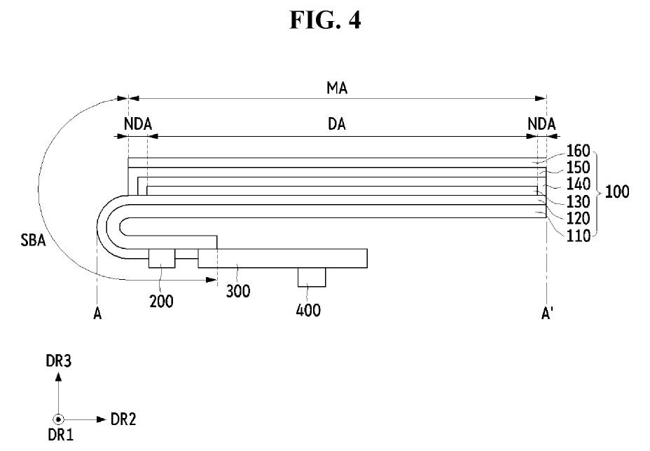

The touch driving circuit 400 may be electrically connected to a touch sensor layer 150 (see FIG. 4) of the display device 100.

As shown in FIG. 2, the bracket 13 may be located under the display device 100.

The bracket 13 may include plastic or metal. The bracket 13 may include a first camera hole CMH1 into which a camera device 16 is inserted, a battery hole BH into which a battery 18 is located, and a cable hole CAH through which the cable 600 connected to the display circuit board 300 passes.

The main circuit board 14 and the battery 18 may be located under the bracket 13.

The main circuit board 14 may be a printed circuit board or a flexible printed circuit board.

The main circuit board 14 may include a main processor 15, the camera device 16, and a main connector 17. The main processor 15 may be formed as an integrated circuit.

The camera device 16 may be located on both the top surface and the bottom surface of the main circuit board 14, the main processor 15 may be located on the top surface of the main circuit board 14, and the main connector 17 may be located on the bottom surface of the main circuit board 14.

The main processor 15 may control all functions of the electronic device 10.

For example, the main processor 15 may output digital video data to the display driving circuit 200 through the display circuit board 300 such that the display device 100 displays an image. In addition, the main processor 15 may receive touch data including user's touch coordinates from the touch driving circuit 400, determine whether or not the user has touched or approached, and then perform an operation corresponding to the user's touch input or approach input. For example, the main processor 15 may perform an operation or execute an application indicated by an icon touched by the user.

The main processor 15 may be an application processor formed as an integrated circuit, a central processing unit, or a system chip.

The camera device 16 processes an image frame of a still image or video obtained by an image sensor in a camera mode and outputs it to the main processor 15.

The cable 600 having passed through the cable hole CAH of the bracket 13 may be connected to the main connector 17. Thus, the main circuit board 14 may be electrically connected to the display circuit board 300.

The battery 18 may be located so as not to overlap the main circuit board 14 in the third direction DR3. The battery 18 may overlap the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 18. The lower cover 12 may be fixed by being fastened to the bracket 13. The lower cover 12 may form the upper side surface, lower side surface, and bottom surface of the electronic device 10. The lower cover 12 may include plastic, metal, or both plastic and metal.

The lower cover 12 may include a second camera hole CMH2 through which the bottom surface of the camera device 16 is exposed. The position of the camera device 16 and the positions of the first camera hole CMH1 and the second camera hole CMH2 corresponding to the camera device 16 are not limited by the illustration in FIG. 2.

Next, further details of the display device 100 according to some embodiments will be described.

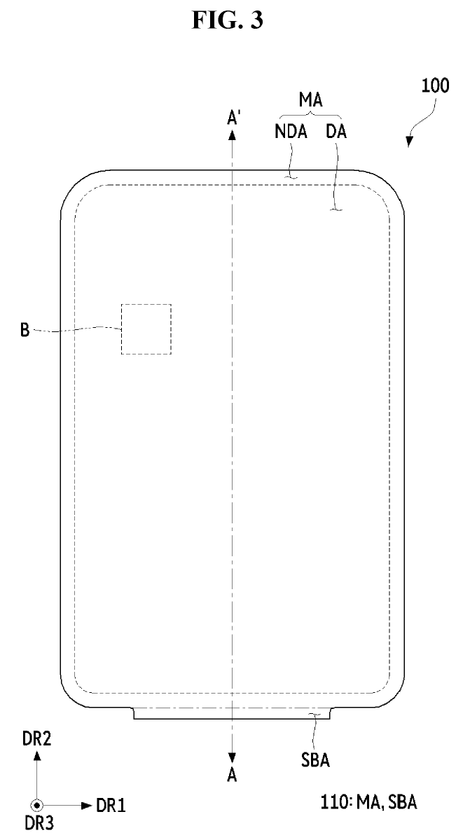

FIG. 3 is a plan view illustrating the display device of FIG. 2. FIG. 4 is a cross-sectional view taken along the line A-A' of FIG. 3.

Referring to FIGS. 3 and 4, the display device 100 according to embodiments, which is a device for displaying a moving image or a still image, may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but embodiments according to the present disclosure are not limited thereto. For example, the display device 100 may include a curved portion formed at left and right ends and having a constant curvature or a varying curvature. In addition, the display device 100 may be formed to be flexible so that it can be curved, bent, folded, or rolled.

Referring to FIG. 3, at least one surface of the display device 100 includes the main region MA from which light for displaying an image is emitted.

The display area DA may, in a plan view, be formed in a rectangular shape having short sides in the first direction DR1 and long sides in the second direction DR2 intersecting the first direction DR1. The corner where the short side in the first direction DR1 and the long side in the second direction DR2 meet may be rounded to have a selected curvature or may be right-angled. The planar shape of the display area DA is not limited to the rectangular shape, and may be formed in another polygonal shape, a circular shape or an elliptical shape.

The display area DA may be located in most of the main region MA. The display area DA may be located at the center of the main region MA.

Referring to FIG. 4, the display device 100 may further include the sub-region SBA protruding in the second direction DR2 from at least a part of one side of the main region MA.

Because a part of the sub-region SBA is transformed into a bent shape, another part of the sub-region SBA may be located on the rear surface of the display device 100.

According to some embodiments, the display device 100 includes a substrate 110, a circuit layer 120 located on the substrate 110, and an element layer 130 located on the circuit layer 120.

The display device 100 may further include an encapsulation layer 140 located on the element layer 130, and a touch sensor layer 150 located on the encapsulation layer 140.

The display device 100 may further include a polarization layer 160 located on the touch sensor layer 150, in order to reduce reflection of external light.

The substrate 110 may include the main region MA corresponding to the display surface, and the sub-region SBA protruding in the second direction DR2 from at least a part of one side of the main region MA.

The main region MA of the substrate 110 may include the display area DA from which light is emitted, and the non-display area NDA located around (e.g., in a periphery or outside a footprint of) the display area DA.

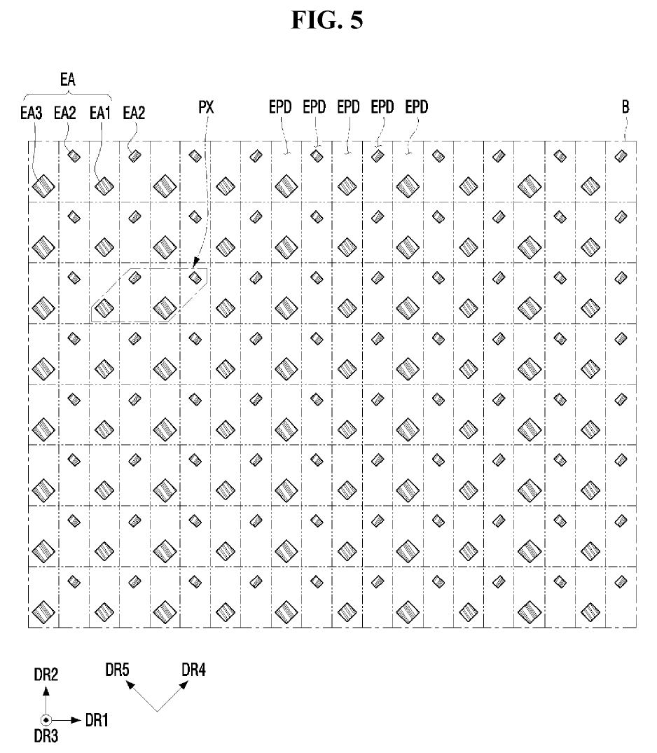

According to some embodiments, the element layer 130 may include light emitting elements LE (see FIGS. 7 and 8) respectively located in the emission areas EA (see FIG. 5).

The circuit layer 120 may include the light emitting pixel drivers EPD (see FIG. 5) electrically connected to light emitting elements LE, and at least one constant voltage line that transmits at least one constant voltage to the light emitting pixel drivers EPD.

At least one constant voltage line may include a first power line VDL (see FIG. 7) that transmits a first power ELVDD (see FIG. 7), an initialization voltage line VIL (see FIG. 7) that transmits an initialization voltage VINT (see FIG. 7), and a reference voltage line VRL (see FIG. 7) that transmits a reference voltage VREF (see FIG. 7).

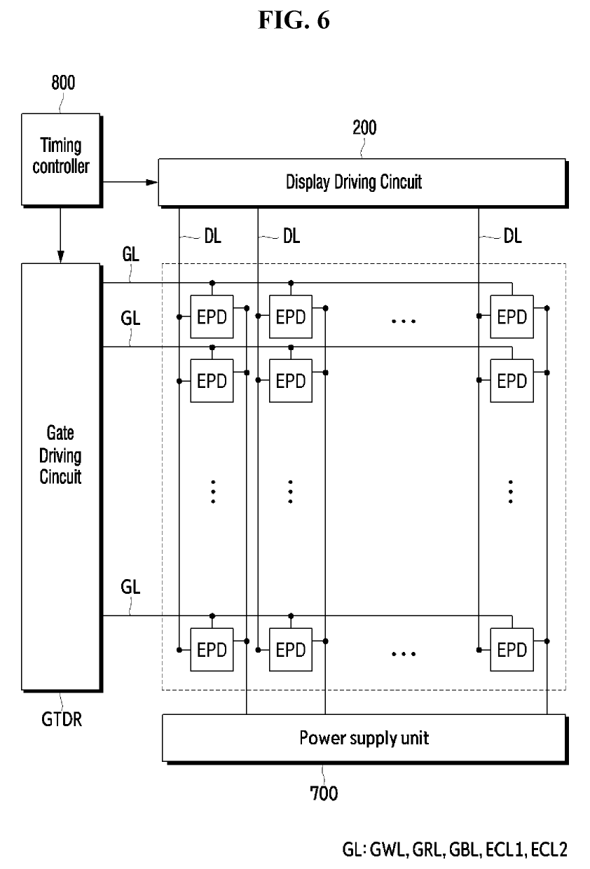

The circuit layer 120 may further include the data lines DL (see FIGS. 6 and 7) that transmit the data signals Vdata (see FIG. 7) of the light emitting pixel drivers EPD (see FIG. 5).

The encapsulation layer 140 may cover the element layer 130. The encapsulation layer 140 may include a structure in which two or more inorganic films and at least one organic film are alternately stacked.

The touch sensor layer 150 may be located on the encapsulation layer 140 and may correspond to the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, and this is to prevent or reduce the deterioration of visibility of an image due to external light reflection.

As a part of the sub-region SBA is transformed into a bent shape, the display driving circuit 200 mounted in the sub-region SBA, and the display circuit board 300 connected to one side of the sub-region SBA may be located under the substrate 110.

The display driving circuit 200 may be electrically connected to the data lines DL (see FIGS. 6 and 7) of the circuit layer 120. The display driving circuit 200 may transmit the data signals Vdata (see FIG. 7) of the light emitting pixel drivers EPD (see FIG. 5) through the data lines DL based on control signals and power voltages supplied from the display circuit board 300.

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and embodiments according to the present disclosure are not limited thereto. For example, the display driving circuit 200 may be mounted on the display circuit board 300.

One end of the display circuit board 300 may be attached onto pads located on one edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

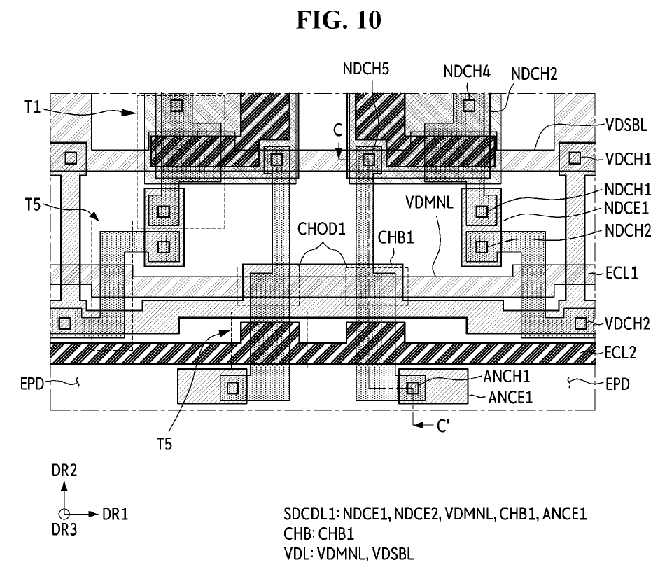

The display circuit board 300 may be connected to signal pads SPD (see FIG. 10) located on one side of the sub-region SBA.

The touch driving circuit 400 may be mounted on the display circuit board 300.

The touch driving circuit 400 may be electrically connected to the touch sensor layer 150 of the display device 100.

The touch driving circuit 400 may apply a touch driving signal to driving lines of the touch sensor layer 150, and receive a touch sensing signal from sensing lines. Further, the touch driving circuit 400 may detect charge variation amounts of capacitances based on the touch sensing signal, thereby determining whether a user has touched or approached.

The user's touch means that an object such as a pen or a user's finger is in direct contact with the top surface of the cover window located on the touch sensor layer. The user's approach means that the object such as the pen or the user's finger hovers over the top surface of the cover window.

The touch driving circuit 400 may output touch data including the user's touch coordinates to the main processor 15 (see FIG. 2).

FIG. 5 is a schematic diagram showing further details of the part B of FIG. 3.

As shown in FIG. 5, the display area DA may include the emission areas EA from which light is emitted, and a non-emission area NEA that is a separation area between the emission areas EA and from which light is not emitted.

Each of the emission areas EA may be a unit area that emits light in a wavelength band corresponding to one color of two or more different colors with a luminance corresponding to an image signal.

Each of the emission areas EA may be arranged in a quadrilateral shape.

However, this is only an example, and the planar shape of the emission areas EA according to some embodiments is not limited to that illustrated in FIG. 5. That is, the emission areas EA may have, in a plan view, a circular shape, an elliptical shape, or a polygonal shape such as a rectangle, a square, a hexagon, or an octagon, rather than a rhombus.

The emission areas EA may include first emission areas EA1 that emit light in a first wavelength band, second emission areas EA2 that emit light in a second wavelength band lower than the first wavelength band, and third emission areas EA3 that emit light in a third wavelength band lower than the second wavelength band.

For example, the first wavelength band may be from about 600 nm to about 750 nm and may correspond to a red color. The second wavelength band may be from about 480 nm to about 560 nm and may correspond to a green color. The third wavelength band may be from about 370 nm to about 460 nm and may correspond to a blue color.

However, this is only an example, and the first wavelength band, the second wavelength band, and the third wavelength band according to some embodiments are not limited thereto.

Because the emission areas EA include the first emission area EA1, the second emission area EA2, and the third emission area EA3, each of unit pixels PX may be provided by a combination of one or more first emission areas EA1, one or more second emission areas EA2, and one or more third emission areas EA3 adjacent to each other among the emission areas EA.

Each of the unit pixels PX may be a unit for displaying various colors including white. That is, lights of various colors displayed by the unit pixels PX may be implemented as a mixture of lights emitted from two or more emission areas EA included in each unit pixel PX.

The third emission area EA3 may have a width greater than that of the first emission area EA1, and the first emission area EA1 may have a width greater than that of the second emission area EA2. However, this is merely an example, and the width of each of the emission areas EA is not limited to that illustrated in FIG. 5.

The first emission areas EA1 and the third emission areas EA3 may be alternately arranged in the second direction DR2.

The second emission areas EA2 may be arranged side by side in the second direction DR2.

Each of the second emission areas EA2 may be adjacent to the first emission area EA1 or the third emission area EA3 in diagonal directions DR4 and DR5 intersecting the first direction DR1 and the second direction DR2.

In this case, each of the unit pixels PX may include one first emission area EA1 and one third emission area EA3 adjacent to each other in the first direction DR1, and two second emission areas EA2 adjacent thereto in the diagonal directions DR4 and DR5. However, this is only an example, and the arrangement pattern of the emission areas EA and the components of the unit pixel PX according to some embodiments are not limited to the above description.

According to some embodiments, the circuit layer 120 (see FIG. 4) may include the light emitting pixel drivers EPD arranged in the first direction DR1 and the second direction DR2 in the display area DA.

The light emitting pixel drivers EPD may be respectively electrically connected to the light emitting elements LE (see FIGS. 7 and 8) of the element layer 130 (see FIG. 4). The light emitting elements LE may be located in the emission areas EA, respectively.

FIG. 6 is a block diagram showing the display device of FIG. 2.

Referring to FIG. 6, the circuit layer 120 of the display device 100 according to some embodiments may include the light emitting pixel drivers EPD electrically connected to the light emitting elements LE (see FIG. 7) located in the emission areas EA of the display area DA, and one or more gate lines GL that transmit one or more gate signals to the light emitting pixel drivers EPD.

The circuit layer 120 may further include the data lines DL that transmit the data signals Vdata (see FIG. 7) of the light emitting pixel drivers EPD.

According to some embodiments, the display device 100 may further include the display driving circuit 200 that outputs the data signals Vdata (see FIG. 8) of the light emitting pixel drivers EPD to the data lines DL in order to control the luminance of each of the light emitting elements LE (see FIG. 7).

According to some embodiments, the display device 100 may further include a gate driver GTDR that outputs gate signals to the gate lines GL, a power supply unit 700 that supplies power and voltages to the light emitting pixel drivers EPD, and a timing controller 800 that controls the driving timing of each of the display driving circuit 200 and the gate driver GTDR.

The timing controller 800 receives an image signal supplied from the outside of the display device 100.

The timing controller 800 may output image data DATA and a data control signal DCS to the display driving circuit 200.

The timing controller 800 may generate the scan control signal SCS for controlling the operation timing of the gate driver GTDR.

The display driving circuit 200 may convert the image data DATA into analog data voltages and output them to the data lines DL.

The gate driver GTDR may generate gate signals in response to the scan control signal SCS and sequentially output the gate signals to gate lines GL.

The gate lines GL may include a scan write line GWL that transmits a scan write signal GW (see FIG. 7), a reset control line GRL that transmits a reset control signal GR (see FIG. 7), a bias control line GBL that transmits a bias control signal GB (see FIG. 7), a first emission control line ECL1 that transmits a first emission control signal EC1 (see FIG. 7), and a second emission control line ECL2 that transmits a second emission control signal EC2 (see FIG. 7).

The gate signals may have pulses that vary to a first gate level voltage or a second gate level voltage.

The power supply unit 700 may supply various power and voltages necessary for driving the light emitting pixel drivers EPD.

For example, the power supply unit 700 may supply the first power ELVDD (see FIG. 7) and a second power ELVSS (see FIG. 7) for generating a driving signal transmitted to the light emitting elements LE, the reference voltage VREF (see FIG. 7) and the initialization voltage VINT (see FIG. 7) for initializing the light emitting elements LE (see FIG. 7).

FIG. 7 is an equivalent circuit diagram showing the light emitting pixel driver of FIG. 6 according to some embodiments. Although FIG. 7 illustrates various components in a light emitting pixel driver according to some embodiments, embodiments according to the present disclosure are not limited thereto, and according to various embodiments, the light emitting pixel driver may include additional components, or fewer components, without departing from the spirit and scope of embodiments according to the present disclosure.

Referring to FIG. 7, the light emitting pixel drivers EPD of the circuit layer 120 (see FIG. 4) may be electrically connected to the light emitting elements LE of the element layer 130 (see FIG. 4), respectively.

The light emitting pixel drivers EPD may be electrically connected to the first power line VDL that transmits the first power ELVDD, and the light emitting elements LE may be electrically connected to the second power line VSL that transmits the second power ELVSS that is different from the first power ELVDD.

The second power ELVSS may be at a voltage level lower than that of the first power ELVDD.

That is, the anode electrode of the light emitting element LE may be electrically connected to the light emitting pixel driver EPD, and the cathode electrode of the light emitting element LE may be electrically connected to the second power line VSL.

The light emitting pixel drivers EPD may be electrically connected to a data line DL that transmits the data signal Vdata, the reference voltage line VRL that transmits the reference voltage VREF, and the initialization voltage line VIL that transmits the initialization voltage VINT.

The light emitting pixel drivers EPD may be electrically connected to the scan write line GWL that transmits the scan write signal GW, the reset control line GRL that transmits the reset control signal GR, the bias control line GBL that transmits the bias control signal GB, the first emission control line ECL1 that transmits the first emission control signal EC1, and the second emission control line ECL2 that transmits the second emission control signal EC2.

Each of the light emitting pixel drivers EPD may include a first transistor T1 generating a driving current of the light emitting element LE, two or more transistors T2 to T6 electrically connected to the first transistor T1, and one or more capacitors C1 and C2.

The second transistor T2 may be electrically connected between the gate electrode of the first transistor T1 and the data line DL.

The second transistor T2 may be turned on by the scan write signal GW of the scan write line GWL.

When the second transistor T2 is turned on, the data signal Vdata of the data line DL may be transmitted to the gate electrode of the first transistor T1.

When the voltage difference between the gate electrode of the first transistor T1 and the second electrode of the first transistor T1 is equal to or greater than the threshold voltage of the first transistor T1 due to the data signal Vdata applied to the gate electrode of the first transistor T1, the first transistor T1 may be turned on. Accordingly, a drain-source current of the first transistor T1 may be generated to have a magnitude corresponding to the data signal Vdata.

A third transistor T3 may be electrically connected between the gate electrode of the first transistor T1 and the reference voltage line VRL.

The third transistor T3 may be turned on by the reset control signal GR of the reset control line GRL.

When the third transistor T3 is turned on, the potential of the gate electrode of the first transistor T1 may be initialized to the reference voltage VREF of the reference voltage line VRL.

The fourth transistor T4 may be electrically connected between the light emitting element LE and the initialization voltage line VIL.

The fourth transistor T4 may be turned on by the bias control signal GB of the bias control line GBL.

When the fourth transistor T4 is turned on, the potential of the anode electrode of the light emitting element LE may be initialized to the initialization voltage VINT of the initialization voltage line VIL.

The fifth transistor T5 may be electrically connected between the first electrode of the first transistor T1 and the first power line VDL.

The fifth transistor T5 may be turned on by the first emission control signal EC1 of the first emission control line ECL1.

The sixth transistor T6 may be electrically connected between the second electrode of the first transistor T1 and the light emitting element LE.

The sixth transistor T6 may be turned on by the second emission control signal EC2 of the second emission control line ECL2.

When the fifth transistor T5 and the sixth transistor T6 are turned on, the first transistor T1 and the light emitting element LE are connected in series between the first power source ELVDD and the second power source ELVSS so that the drain-source current of the first transistor T1 generated to have a magnitude corresponding to the data signal Vdata may be transmitted to the light emitting element LE.

Accordingly, the light emitting element LE may emit light having a luminance corresponding to the data signal Vdata.

The first capacitor C1 may be electrically connected between the gate electrode of the first transistor T1 and the second electrode of the first transistor T1.

Accordingly, the first capacitor C1 may be charged with the data signal Vdata applied to the gate electrode of the first transistor T1, and the turn-on of the first transistor T1 may be maintained for a selected period due to the voltage charged in the first capacitor C1.

A second capacitor C2 may be electrically connected between the second electrode of the first transistor T1 and the first power line VDL.

The voltage of the first capacitor C1 may correspond to the potential difference between the gate electrode of the first transistor T1 and the second electrode of the first transistor T1, may be changed by the data signal Vdata, and may be divided by the second capacitor C2. Accordingly, the threshold voltage of the first transistor T1 may be compensated.

According to some embodiments, the first transistor T1 may include the gate electrode facing one surface of a channel portion and a gate additional electrode facing the other surface of the channel portion. That is, the channel portion of the first transistor T1 may be interposed between the gate electrode and the gate additional electrode.

The gate electrode of the first transistor T1 may be electrically connected to the second transistor T2.

The gate additional electrode of the first transistor T1 may be electrically connected to the second electrode of the first transistor T1.

Accordingly, when the data signal Vdata is applied to the gate electrode of the first transistor T1 such that the first transistor T1 is in a turned-on state, compared to a portion of the channel portion of the first transistor T1, which is adjacent to the gate electrode, the other portion of the channel portion of the first transistor T1, which is adjacent to the gate additional electrode, may not be activated.

Therefore, because the electron mobility in the channel portion of the first transistor T1 decreases, the slope of a current curve representing a relationship between the drain-source current and the voltage of the gate electrode of the first transistor T1 may become gentle. Accordingly, a driving voltage range of the first transistor T1 may be widened, which may facilitate luminance control.

According to some embodiments, the first transistor T1 may be an N-type MOSFET.

Further, at least some of the second to sixth transistors T2 to T6 may be P-type MOSFETs.

For example, the fifth transistor T5 may be a P-type MOSFET, and the second transistor T2, the third transistor T3, the fourth transistor T4, and the sixth transistor T6 may be N-type MOSFETs.

Accordingly, according to some embodiments, the circuit layer 120 may include a first semiconductor layer SEL1 (see FIG. 8) for providing a P-type MOSFET and a second semiconductor layer SEL2 (see FIG. 8) for providing an N-type MOSFET.

FIG. 8 is a cross-sectional view showing the first transistor, the fifth transistor, the sixth transistor, and the light emitting element of FIG. 7.

Referring to FIG. 8, the display device 100 according to some embodiments may include the substrate 110, the circuit layer 120 on the substrate 110, and the element layer 130 on the circuit layer 120.

The display device 100 may further include the encapsulation layer 140 on the element layer 130.

According to some embodiments, the circuit layer 120 may include the first semiconductor layer SEL1 located on the substrate 110, a first interlayer insulating layer 124 located on the first semiconductor layer SEL1, and the second semiconductor layer SEL2 located on the first interlayer insulating layer 124 and including an oxide semiconductor material.

The circuit layer 120 may further include a first gate insulating layer 122 covering the first semiconductor layer SEL1, a first gate conductive layer GCDL1 located on the first gate insulating layer 122, a second gate insulating layer 123 covering the first gate conductive layer GCDL1, a second gate conductive layer GCDL2 located on the second gate insulating layer 123, a third gate insulating layer 125 covering the second semiconductor layer SEL2, a third gate conductive layer GCDL3 located on the third gate insulating layer 125, and a first source-drain conductive layer SDCDL1 located on a second interlayer insulating layer 126.

The first interlayer insulating layer 124 covers the second gate conductive layer GCDL2, and the second interlayer insulating layer 126 covers the third gate conductive layer GCDL3.

According to some embodiments, the circuit layer 120 may further include a first planarization layer 127 covering the first source-drain conductive layer SDCDL1, a second source-drain conductive layer SDCDL2 located on the first planarization layer 127, and a second planarization layer 128 covering the second source-drain conductive layer SDCDL2.

According to some embodiments, the circuit layer 120 may further include the buffer layer 121 covering the substrate 110. In this case, the first semiconductor layer SEL1 may be located on the buffer layer 121.

As illustrated in FIG. 7, each of the light emitting pixel drivers EPD may include the first transistor T1, and the second transistor T2, the third transistor T3, the fourth transistor T4, the fifth transistor T5, the sixth transistor T6, the first capacitor C1, and the second capacitor C2 that are electrically connected to the first transistor T1.

Each of the first transistor T1, the second transistor T2, the third transistor T3, the fourth transistor T4, the fifth transistor T5, and the sixth transistor T6 may include a gate electrode, a channel portion overlapping the gate electrode, a first electrode portion connected to one side of the channel portion, and a second electrode portion connected to the other side of the channel portion.

In the following, the "first electrode portion" and the "second electrode portion" electrically connected to the two opposite ends of the "channel portion" of the "transistor" may also be referred to as the "first electrode" and the "second electrode," respectively.

According to some embodiments, the first, second, third, fourth and sixth transistors T1, T2, T3, T4, and T6 may be N-type MOSFETs, and the fifth transistor T5 may be a P-type MOSFET.

The channel portion CH5, the first electrode portion E15, and the second electrode portion E25 of the fifth transistor T5 formed as a P-type MOSFET may be located in the first semiconductor layer SEL1.

The gate electrode G5 of the fifth transistor T5 may be located in the first gate conductive layer GCDL1.

For example, the first semiconductor layer SEL1 may include a silicon semiconductor material such as polysilicon or amorphous silicon.

That is, the fifth transistor T5 may include the channel portion CH5 located in the first semiconductor layer SEL1, the first electrode portion E15 located in the first semiconductor layer SEL1 and connected to one side of the channel portion CH5, the second electrode portion E25 located in the first semiconductor layer SEL1 and connected to the other side of the channel portion CH5, and the gate electrode G5 located in the first gate conductive layer GCDL1 and overlapping the channel portion CH5.

The first electrode portion E15 of the fifth transistor T5 may be electrically connected to the first power line VDL.

The first power line VDL may include a power sub-line VDSBL located in the first gate conductive layer GCDL1, and a power main line VDMNL located in the first source-drain conductive layer SDCDL1.

The power main line VDMNL may be electrically connected to the power sub-line VDSBL through a first power connection hole VDCH1.

The power main line VDMNL may be electrically connected to the first electrode portion E15 of the fifth transistor T5 through a second power connection hole VDCH2.

Alternatively, the first power line VDL may further include a power additional line VDAL located in the second source-drain conductive layer SDCDL2.

The power additional line VDAL may extend in a direction intersecting the power main line VDMNL and may be electrically connected to the power main line VDMNL.

In this way, the first power ELVDD (see FIG. 7) may be transmitted relatively evenly throughout the entire display area DA through mesh-shaped lines.

The channel portions CH1 and CH6, the first electrode portions E11 and E16, and the second electrode portions E21 and E26 of the first transistor T1 and the sixth transistor T6 that are formed as N-type MOSFETs may be located in the second semiconductor layer SEL2.

The gate electrodes G1 and G6 of the first transistor T1 and the sixth transistor T6 may each be located in the third gate conductive layer GCDL3.

The second semiconductor layer SEL2 may include an oxide semiconductor material.

The first transistor T1 may include the channel portion CH1 located in the second semiconductor layer SEL2, the first electrode portion E11 located in the second semiconductor layer SEL2 and connected to one side of the channel portion CH1, the second electrode portion E21 located in the second semiconductor layer SEL2 and connected to the other side of the channel portion CH1, and the gate electrode G1 located in the third gate conductive layer GCDL3 and overlapping the channel portion CH1.

The top surface of the channel portion CH1 of the first transistor T1 may face the gate electrode G1.

In addition, the bottom surface of the channel portion CH1 of the first transistor T1 may face a third capacitor electrode CPE3 electrically connected to the second electrode portion E21 of the first transistor T1.

That is, the third capacitor electrode CPE3 may be the gate additional electrode of the first transistor T1.

The sixth transistor T6 may include the channel portion CH6 located in the second semiconductor layer SEL2, the first electrode portion E16 located in the second semiconductor layer SEL2 and connected to one side of the channel portion CH6, the second electrode portion E26 located in the second semiconductor layer SEL2 and connected to the other side of the channel portion CH6, and the gate electrode G6 located in the third gate conductive layer GCDL3 and overlapping the channel portion CH6.

The first electrode portion E11 of the first transistor T1 may be electrically connected to the second electrode portion E25 of the fifth transistor T5 through the first node connection electrode NDCE1.

The first node connection electrode NDCE1 may be located in the first source-drain conductive layer SDCDL1.

The first node connection electrode NDCE1 may be electrically connected to the first electrode portion E11 of the first transistor T1 through a first node connection hole NDCH1.

The first node connection electrode NDCE1 may be electrically connected to the second electrode portion E25 of the fifth transistor T5 through a second node connection hole NDCH2.

The second electrode portion E21 of the first transistor T1 may be electrically connected to the first electrode portion E16 of the sixth transistor T6 and the third capacitor electrode CPE3 through a second node connection electrode NDCE2.

The second node connection electrode NDCE2 may be located in the first source-drain conductive layer SDCDL1.

The second node connection electrode NDCE2 may be electrically connected to the second electrode portion E21 of the first transistor T1 through a third node connection hole NDCH3.

The second node connection electrode NDCE2 may be electrically connected to the third capacitor electrode CPE3 through a fourth node connection hole NDCH4.

The second node connection electrode NDCE2 may be electrically connected to the first electrode portion E16 of the sixth transistor T6 through a fifth node connection hole NDCH5.

The second electrode portion E26 of the sixth transistor T6 may be electrically connected to the anode electrode 131 of the light emitting element LE through the first anode connection electrode ANCE1 and the second anode connection electrode ANCE2.

The first anode connection electrode ANCE1 may be located in the first source-drain conductive layer SDCDL1 on the second interlayer insulating layer 126, and may be electrically connected to the second electrode portion E26 of the six transistor T6 through a first anode connection hole ANCH1.

The first anode connection hole ANCH1 may penetrate the second interlayer insulating layer 126, the third gate insulating layer 125, the first interlayer insulating layer 124, the second gate insulating layer 123, and the first gate insulating layer 122.

The second anode connection electrode ANCE2 may be located in the second source-drain conductive layer SDCDL2 on the first planarization layer 127, and electrically connected to the first anode connection electrode ANCE1 through a second anode connection hole ANCH2 penetrating the first planarization layer 127.

The anode electrode 131 may be located on the second planarization layer 128, and may be electrically connected to the second anode connection electrode ANCE2 through a third anode contact hole ANCH3 penetrating the second planarization layer 128.

The first gate conductive layer GCDL1 may include the first capacitor electrode CPE1 and the second capacitor electrode CPE2.

The second gate conductive layer GCDL2 may include the third capacitor electrode CPE3 overlapping the first capacitor electrode CPE1 and the second capacitor electrode CPE2.

The first capacitor electrode CPE1 may be electrically connected to the gate electrode G1 of the first transistor T1.

Because the third capacitor electrode CPE3 is electrically connected to the second electrode portion E21 of the first transistor T1, the first capacitor C1 may be formed by an area in which the first capacitor electrode CPE1 and the third capacitor electrode CPE3 overlap each other.

The third capacitor electrode CPE3 may be electrically connected to the second electrode portion E21 of the first transistor T1 through the second node connection electrode NDCE2.

That is, the second node connection electrode NDCE2 is at the same potential as the second electrode portion E21 of the first transistor T1. Accordingly, the first capacitor C1 may also be formed by an area in which the gate electrode G1 of the first transistor T1 and the second node connection electrode NDCE2 overlap each other.

The second capacitor electrode CPE2 may be connected to the power sub-line VDSBL located in the first gate conductive layer GCDL1 among the first power lines VDL.

Accordingly, the second capacitor C2 may be formed by a region where the second capacitor electrode CPE2 and the third capacitor electrode CPE3 overlap each other.

The second source-drain conductive layer SDCDL2 may include the data line DL.

The element layer 130 may be located on the circuit layer 120, and may include the light emitting elements LE respectively corresponding to the emission areas EA.

Each of the light emitting elements LE may include the anode electrode 131 and a cathode electrode 134 facing each other, and a light emitting layer 133 located between the anode electrode 131 and the cathode electrode 134.

That is, the element layer 130 may include the anode electrodes 131 located in the emission areas EA, a pixel defining layer 132 located in the non-emission area and covering the edge of the anode electrode 131, the light emitting layers 133 located on the anode electrodes 131, and the cathode electrode 134 located on the light emitting layers 133 and the pixel defining layer 132.

Alternatively, each of the light emitting elements LE may further include a first common layer located between the anode electrode 131 and the light emitting layer 133, and a second common layer located between the light emitting layer 133 and the cathode electrode 134.

The anode electrode 131 may be located in each of the emission areas EA and may be electrically connected to one light emitting pixel driver EPD of the circuit layer 120. This anode electrode 131 may be referred to as a pixel electrode.

The anode electrode 131 may be located on the second planarization layer 128, and may be electrically connected to the second anode connection electrode ANCE2 through a third anode connection hole ANCH3 penetrating the second planarization layer 128.

The light emitting layer 133 may include an organic light emitting material that converts an electron-hole pair into light.

The cathode electrode 134 may be located in the display area DA including the emission areas EA. Because the second power ELVSS (see FIG. 7) is commonly applied to the cathode electrode 134, it may be a portion of the second power line VSL (see FIG. 7). The cathode electrode 134 may be referred to as a common electrode.

The encapsulation layer 140 may be located on the circuit layer 120 and cover the element layer 130.

As an example, the encapsulation layer 140 may include a first encapsulation layer located on the element layer 130 and made of an inorganic insulating material, a second encapsulation layer located on the first encapsulation layer, overlapping the element layer 130, and made of an organic insulating material, and a third encapsulation layer located on the first encapsulation layer, covering the second encapsulation layer, and made of an inorganic insulating material.

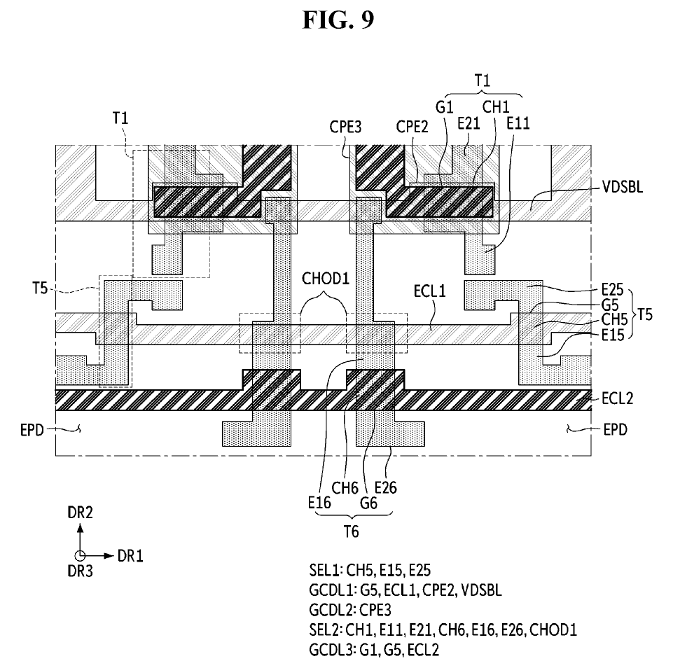

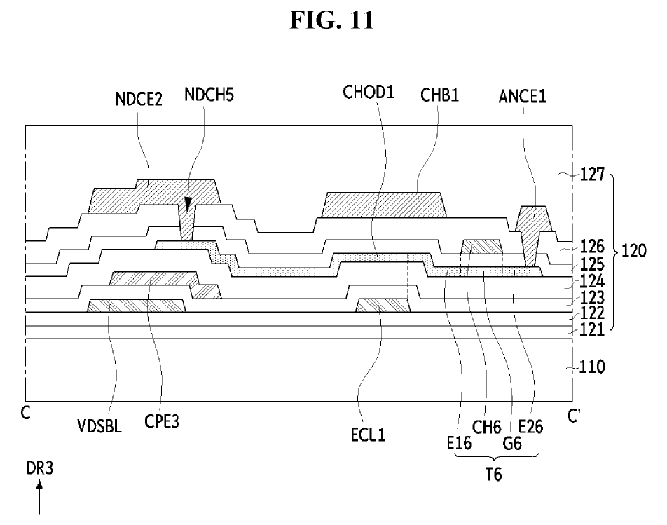

FIGS. 9 and 10 are plan views illustrating a first transistor, a fifth transistor, a sixth transistor, and a first channel bias portion according to some embodiments as illustrated in FIG. 7. FIG. 11 is a cross-sectional view taken along the line C-C' of FIG. 10.

FIGS. 9 and 10 are plan views illustrating a portion of each of two adjacent light emitting pixel drivers EPD in the first direction DR1.

FIG. 9 is a plan view illustrating a first semiconductor layer, a first gate conductive layer, a second gate conductive layer, a second semiconductor layer, and a third gate conductive layer.

FIG. 10 is a plan view illustrating a first source-drain conductive layer, along with the plan view of FIG. 9.

As illustrated in FIG. 10, the first semiconductor layer SEL1 may include the channel portion CH5, the first electrode portion E15, and the second electrode portion E25 of the fifth transistor T5 formed as a P-type MOSFET.

The first gate conductive layer GCDL1 may include the gate electrode G5 of the fifth transistor T5, the first emission control line ECL1, the second capacitor electrode CPE2, and the power sub-line VDSBL.

Each of the first emission control line ECL1 and the power sub-line VDSBL may extend in the first direction DR1.

The gate electrode G5 of the fifth transistor T5 may be a portion of the first emission control line ECL1 intersecting the first semiconductor layer SEL1.

In other words, a portion of the first semiconductor layer SEL1 intersecting the first emission control line ECL1 may be the channel portion CH5 of the fifth transistor T5.

The second capacitor electrode CPE2 may be a portion of the power sub-line VDSBL.

The second gate conductive layer GCDL2 may include the third capacitor electrode CPE3.

The second semiconductor layer SEL2 may include the channel portions CH1 and CH6, the first electrode portions E11 and E16, and the second electrode portions E21 and E26 of the first transistor T1 and the sixth transistor T6, respectively, which are formed as N-type MOSFETs.

The third gate conductive layer GCDL3 may include the gate electrodes G1 and G6 of the first transistor T1 and the sixth transistor T6, respectively, and the second emission control line ECL2.

The channel portion CH1 of the first transistor T1 is a portion of the second semiconductor layer SEL2 overlapping the gate electrode G1 of the first transistor T1.

The first electrode portion E11 of the first transistor T1 may be connected to one side of the channel portion CH1 of the first transistor T1 and may be located adjacent to the second electrode portion E25 of the fifth transistor T5.

The second electrode portion E21 of the first transistor T1 is connected to the other side of the channel portion CH1 of the first transistor T1.

The gate electrode G1 of the first transistor T1 may overlap each of the second capacitor electrode CPE2 and the third capacitor electrode CPE3.

The second emission control line ECL2 may extend in the first direction DR1.

As illustrated in FIGS. 10 and 11, the channel portion CH6 of the sixth transistor T6 is a portion of the second semiconductor layer SEL2 intersecting the second emission control line ECL2.

That is, the gate electrode G6 of the sixth transistor T6 may be a portion of the second emission control line ECL2 intersecting the second semiconductor layer SEL2.

The first electrode portion E16 of the sixth transistor T6 may be connected to one side of the channel portion CH6 of the sixth transistor T6 and may be adjacent to or overlap the third capacitor electrode CPE3.

The second electrode portion E26 of the sixth transistor T6 is connected to the other side of the channel portion CH6 of the sixth transistor T6.

According to some embodiments, the first emission control line ECL1 may be located between the first transistor T1 and the second emission control line ECL2 in the second direction DR2. As a result, the first emission control line ECL1 may intersect the second semiconductor layer SEL2.

Accordingly, the second semiconductor layer SEL2 may include a first non-design channel portion CHOD1 overlapping the first emission control line ECL1.

When the first non-design channel portion CHOD1 maintains semiconductor characteristics, a defect may occur in which a switch that operates in a turned-on state and a turned-off state according to the first emission control signal EC1 (see FIG. 7) is added between the first transistor T1 and the sixth transistor T6.

Accordingly, as illustrated in FIGS. 10 and 11, the circuit layer 120 of the display device 100 according to some embodiments includes a channel bias portion CHB that overlaps a portion of the second semiconductor layer SEL2 and overlaps at least one constant voltage line, to reduce the influence of the first non-design channel portion CHOD1.

The channel bias portion CHB may include a first channel bias portion CHB1 that overlaps the first non-design channel portion CHOD1 of the second semiconductor layer SEL2 and protrudes from the power main line VDMNL.

As illustrated in FIG. 10, the first source-drain conductive layer SDCDL1 may include the first node connection electrode NDCE1, the second node connection electrode NDCE2, the first anode connection electrode ANCE1, the power main line VDMNL, and the first channel bias portion CHB1.

The first node connection electrode NDCE1 may be electrically connected to the first electrode portion E11 (see FIG. 9) of the first transistor T1 through the first node connection hole NDCH1.

The first node connection electrode NDCE1 may be electrically connected to the second electrode portion E25 (see FIG. 9) of the fifth transistor T5 through the second node connection hole NDCH2.

The second node connection electrode NDCE2 may be electrically connected to the second electrode portion E21 (see FIG. 9) of the first transistor T1 through the fourth node connection hole NDCH4.

The second node connection electrode NDCE2 may be electrically connected to the first electrode portion E16 (see FIG. 9) of the sixth transistor T6 through the fifth node connection hole NDCH5.

The first anode connection electrode ANCE1 may be electrically connected to the second electrode portion E26 (see FIG. 9) of the sixth transistor T6 through the first anode connection hole ANCH1.

The first power line VDL may include the power sub-line VDSBL located in the first gate conductive layer GCDL1 (see FIG. 9) and extending in the first direction DR1, and the power main line VDMNL located in the first source-drain conductive layer SDCDL1 and extending in the first direction DR1.

The power main line VDMNL may be electrically connected to the power sub-line VDSBL through the first power connection hole VDCH1.

The power main line VDMNL may be electrically connected to the first electrode portion E15 (see FIG. 9) of the fifth transistor T5 through the second power connection hole VDCH2.

The first channel bias portion CHB1 may overlap the first non-design channel portion CHOD1 and may protrude from the power main line VDMNL.

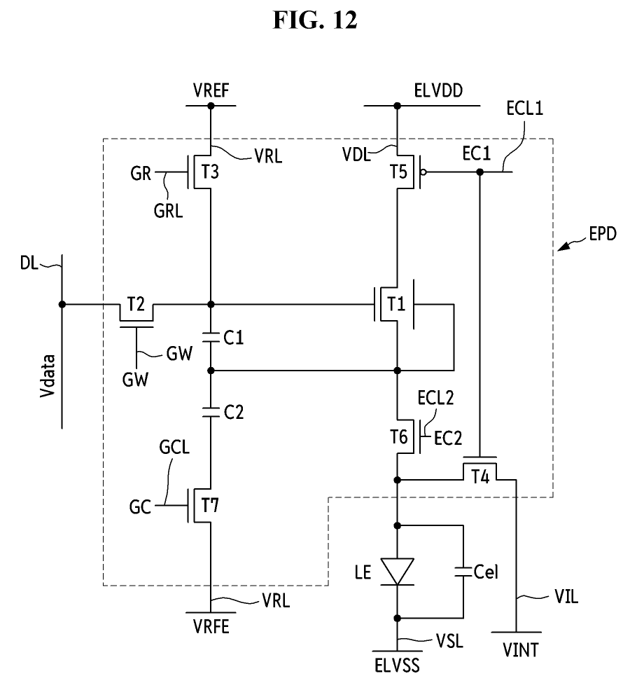

As illustrated in FIG. 12, the first non-design channel portion CHOD1 may be located between the first emission control line ECL1 and the first channel bias portion CHB1 in the third direction DR3.

The first channel bias portion CHB1 may be a portion of the power main line VDMNL and may be maintained by the first power ELVDD (see FIG. 7).

Accordingly, although the first non-design channel portion CHOD1 has semiconductor characteristics, it may be maintained in a turned-on state by the first power ELVDD (see FIG. 7) of the first channel bias portion CHB1. That is, the first non-design channel portion CHOD1 may not switch according to the first emission control signal EC1 (see FIG. 7) of the first emission control line ECL1.

Accordingly, because malfunction of the light emitting pixel driver EPD due to the first non-design channel portion CHOD1 may be prevented or reduced, the display quality of the display device 100 may be relatively improved without significantly changing the arrangement of the lines.

FIG. 12 is an equivalent circuit diagram showing the light emitting pixel driver of FIG. 6 according to some embodiments. Although FIG. 12 illustrates various components in a light emitting pixel driver according to some embodiments, embodiments according to the present disclosure are not limited thereto, and according to various embodiments, the light emitting pixel driver may include additional components, or fewer components, without departing from the spirit and scope of embodiments according to the present disclosure.

The display device 100 according to some embodiments as illustrated in FIG. 12 is substantially the same as or similar to the display device 100 according to some embodiments as illustrated in FIG. 7, except that each of the light emitting pixel drivers EPD further includes a seventh transistor T7, the second capacitor C2 is electrically connected to the seventh transistor T7, and the fourth transistor T4 is turned on in response to the first emission control signal EC1, so that some redundant description may be omitted below.

According to some embodiments as illustrated in FIG. 12, the light emitting pixel drivers EPD may include the first transistor T1, the second transistor T2, the third transistor T3, the fourth transistor T4, the fifth transistor T5, and the sixth transistor T6.

According to some embodiments as illustrated in FIG. 12, the gate electrode of the fourth transistor T4 may be electrically connected to the first emission control line ECL1.

According to some embodiments as illustrated in FIG. 12, the light emitting pixel drivers EPD may further include the first capacitor C1 electrically connected between the gate electrode of the first transistor T1 and the second electrode portion of the first transistor T1, and the second capacitor C2 and the seventh transistor T7 connected in series between the second electrode portion of the first transistor T1 and the reference voltage line VRL.

The seventh transistor T7 may be formed as an N-type MOSFET.

One end of the first capacitor C1 may be electrically connected to the gate electrode of the first transistor T1, and the other end of the first capacitor C1 may be electrically connected to the second electrode portion of the first transistor T1.

The first electrode portion of the seventh transistor T7 may be electrically connected to the reference voltage line VRL.

One end of the second capacitor C2 may be electrically connected to the second electrode portion of the first transistor T1, and the other end of the second capacitor C2 may be electrically connected to the second electrode portion of the seventh transistor T7.

The gate electrode of the seventh transistor T7 may be electrically connected to a gate control line GCL that transmits a gate control signal GC.

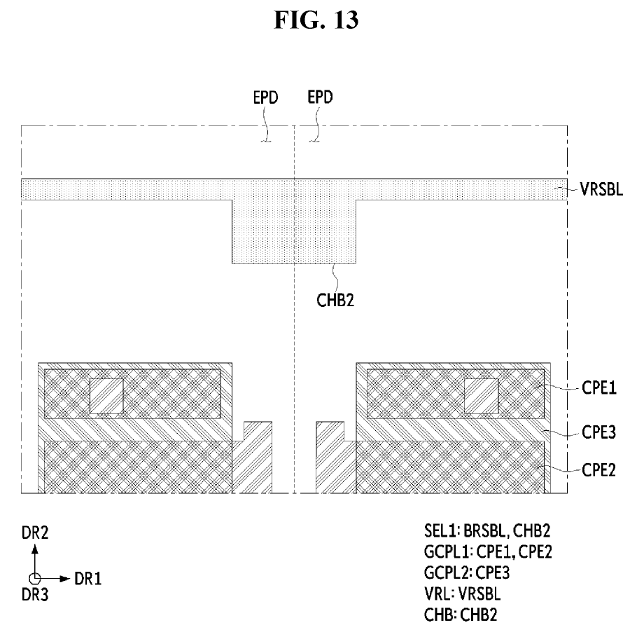

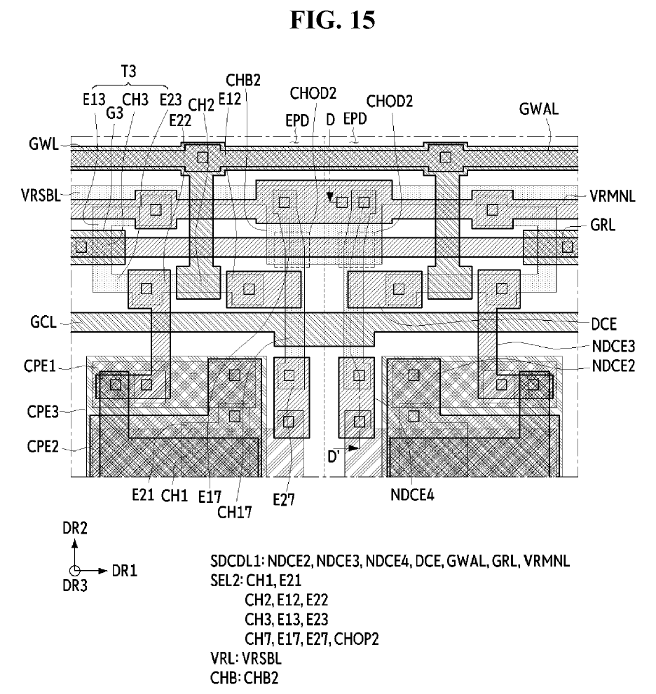

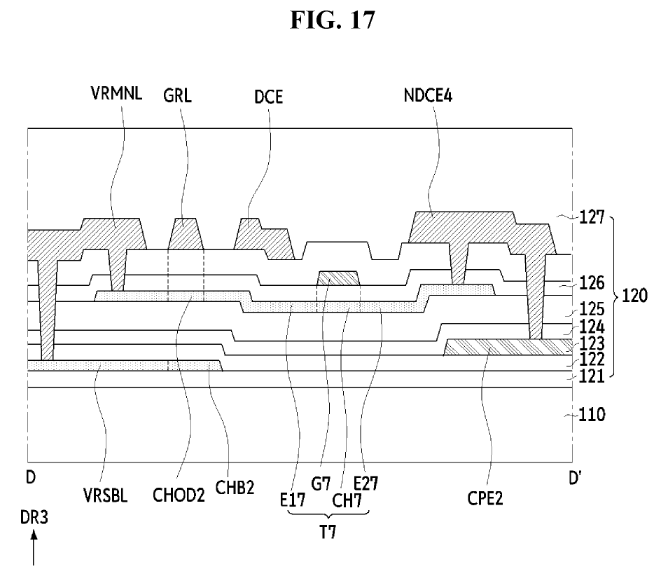

FIGS. 13, 14, 15, and 16 are plan views illustrating a first transistor, a second transistor, a third transistor, a seventh transistor, and a second channel bias portion according to some embodiments as illustrated in FIG. 12. FIG. 17 is a cross-sectional view taken along the line D-D' of FIG. 15.

FIGS. 13, 14, 15 and 16 are plan views illustrating a portion of each of two adjacent light emitting pixel drivers EPD in the first direction DR1.

FIG. 13 is a plan view illustrating a first semiconductor layer, a first gate conductive layer, and a second gate conductive layer.

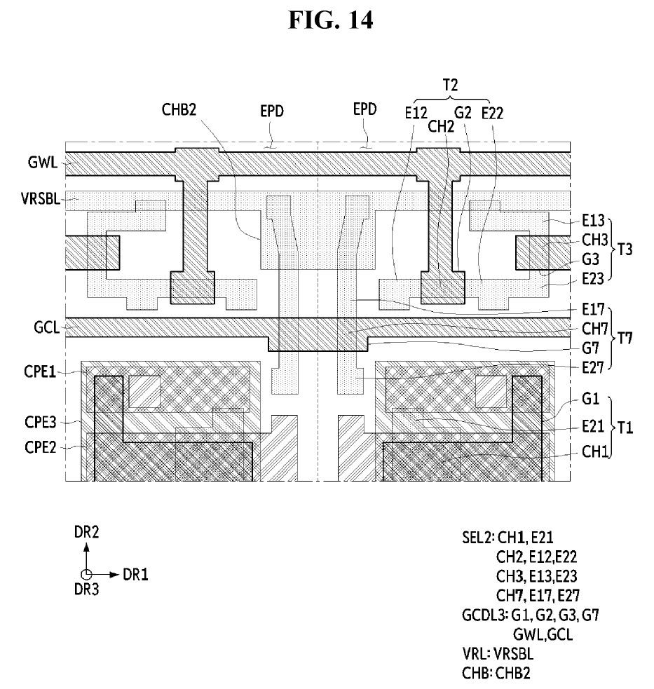

FIG. 14 is a plan view illustrating a second semiconductor layer and a third gate conductive layer, along with the plan view of FIG. 13.

FIG. 15 is a plan view illustrating a first source-drain conductive layer, along with the plan view of FIG. 14.

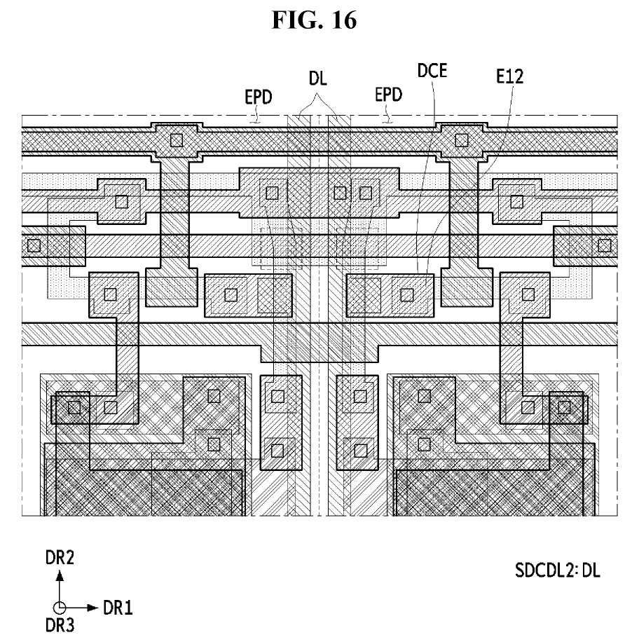

FIG. 16 is a plan view illustrating a second source-drain conductive layer, along with the plan view of FIG. 15.

As illustrated in FIG. 13, the reference voltage line VRL may include a reference voltage sub-line VRSBL located in the first semiconductor layer SEL1 and extending in the first direction DR1.

According to some embodiments, the channel bias portion CHB configured to offset the switching operation of the non-design channel portion may include a second channel bias portion CHB2 protruding from the reference voltage sub-line VRSBL.

Because the reference voltage sub-line VRSBL and the second channel bias portion CHB2 do not overlap the first emission control line ECL1 (see FIG. 9), they may be conductive portions of the first semiconductor layer SEL1.

The first gate conductive layer GCDL1 may include the first capacitor electrode CPE1 and the second capacitor electrode CPE2 spaced apart from each other.

According to some embodiments as illustrated in FIG. 12, each of the first capacitor electrode CPE1 and the second capacitor electrode CPE2 may be located in an island shape.

The second gate conductive layer GCDL2 may include the third capacitor electrode CPE3 overlapping the first capacitor electrode CPE1 and the second capacitor electrode CPE2.

A hole that overlaps the first capacitor electrode CPE1 may be formed in the third capacitor electrode CPE3.

As illustrated in FIG. 14, the second semiconductor layer SEL2 may include the channel portions CH1, CH2, CH3, and CH7, the first electrode portion E11 (see FIG. 9) and the first electrode portions E12, E13, and E17 (see FIG. 14), and the second electrode portions E21, E22, E23, and E27 of the first transistor T1, the second transistor T2, the third transistor T3, and the seventh transistor T7, respectively, which are formed as N-type MOSFETs.

The third gate conductive layer GCDL3 may include the gate electrodes G1, G2, G3, and G7 of the first transistor T1, the second transistor T2, the third transistor T3, and the seventh transistor T7, respectively, the scan write line GWL, and the gate control line GCL.

Each of the scan write line GWL and the gate control line GCL may extend in the first direction DR1.

The first transistor T1 may overlap the third capacitor electrode CPE3.

The gate electrode G2 of the second transistor T2 may be a portion of the scan write line GWL.

That is, a portion of the second semiconductor layer SEL2 overlapping the scan write line GWL may be the channel portion CH2 of the second transistor T2.

The first electrode portion E12 of the second transistor T2 may be connected to one side of the channel portion CH2 of the second transistor T2.

The second electrode portion E22 of the second transistor T2 may be connected to the other side of the channel portion CH2 of the second transistor T2 and the second electrode portion E23 of the third transistor T3.

The first electrode portion E13 of the third transistor T3 may be located adjacent to the reference voltage sub-line VRSBL.

The gate electrode G7 of the seventh transistor T7 may be a portion of the gate control line GCL.

That is, a portion of the second semiconductor layer SEL2 overlapping the gate control line GCL may be the channel portion CH7 of the seventh transistor T7.

The first electrode portion E17 of the seventh transistor T7 may be connected to one side of the channel portion CH7 of the seventh transistor T7 and may be adjacent to or overlap the reference voltage sub-line VRSBL.

The second electrode portion E27 of the seventh transistor T7 may be connected to the other side of the channel portion CH7 of the seventh transistor T7 and may be located adjacent to the third capacitor electrode CPE3.

As illustrated in FIG. 15, the first source-drain conductive layer SDCDL1 may include the second node connection electrode NDCE2, the third node connection electrode NDCE3, the fourth node connection electrode NDCE4, a data connection electrode DCE, a scan write additional line GWAL, the reset control line GRL, and a reference voltage main line VRMNL.

Each of the scan write additional line GWAL, the reset control line GRL, and the reference voltage main line VRMNL may extend in the first direction DR1.

The scan write additional line GWAL may overlap the scan write line GWL and may be electrically connected to the scan write line GWL.

The reset control line GRL may be electrically connected to the gate electrode G3 of the third transistor T3.

The reference voltage line VRL may include the reference voltage sub-line VRSBL located in the first semiconductor layer SEL1 (see FIG. 13), and the reference voltage main line VRMNL located in the first source-drain conductive layer SDCDL1 and electrically connected to the reference voltage sub-line VRSBL.

The reference voltage main line VRMNL may be electrically connected to the reference voltage sub-line VRSBL, as well as the first electrode portion E13 of the third transistor T3 (see FIG. 14) and the first electrode portion E17 of the seventh transistor T7 (see FIG. 14).

The second node connection electrode NDCE2 may be electrically connected to the second electrode portion E21 of the first transistor T1 (see FIG. 14) and the third capacitor electrode CPE3.

The third node connection electrode NDCE3 may be electrically connected to the second electrode portion E22 of the second transistor T2 (see FIG. 14), the second electrode portion E23 of the third transistor T3 (see FIG. 14), the gate electrode G1 of the first transistor T1 (see FIG. 14), and the first capacitor electrode CPE1.

The fourth node connection electrode NDCE4 may be electrically connected to the second electrode portion E27 of the seventh transistor T7 (see FIG. 14) and the second capacitor electrode CPE2.

The data connection electrode DCE may be electrically connected to the first electrode portion E12 of the second transistor T2 (see FIG. 14).

As illustrated in FIG. 16, the second source-drain conductive layer SDCDL2 may include the data line DL extending in the second direction DR2.

The data line DL may be electrically connected to the first electrode portion E12 of the second transistor T2 (see FIG. 14) through the data connection electrode DCE.

As illustrated in FIG. 15, according to some embodiments, the reset control line GRL may be located between the reference voltage line VRL and the gate control line GCL in the second direction DR2.

Accordingly, when the first electrode portion E17 of the seventh transistor T7 extends from the channel portion CH7 of the seventh transistor T7 to the reference voltage line VRL, the reset control line GRL may intersect the first electrode portion E17 of the seventh transistor T7.

Accordingly, the second semiconductor layer SEL2 may include a second non-design channel portion CHOD2 located between the reference voltage line VRL and the gate control line GCL and intersecting the reset control line GRL.

When the second non-design channel portion CHOD2 maintains semiconductor characteristics, a defect may occur in which a switch that operates in a turned-on state and a turned-off state according to the reset control signal GR (see FIG. 7) of the reset control line GRL is added between the reference voltage line VRL and the seventh transistor T7.

Accordingly, as illustrated in FIG. 15, the circuit layer 120 of the display device 100 according to some embodiments includes the channel bias portion CHB that overlaps a portion of the second semiconductor layer SEL2 and is electrically connected to at least one constant voltage line, to reduce the influence of the second non-design channel portion CHOD2.

The channel bias portion CHB may include a second channel bias portion CHB2 that overlaps the second non-design channel portion CHOD2 of the second semiconductor layer SEL2 and protrudes from the reference voltage sub-line VRSBL.

As illustrated in FIG. 17, the second non-design channel portion CHOD2 may be located between the reset control line GRL and the second channel bias portion CHB2 in the third direction DR3.

The second channel bias portion CHB2 is a portion of the reference voltage sub-line VRSBL and is maintained at the reference voltage VREF (see FIG. 7).

Accordingly, although the second non-design channel portion CHOD2 has semiconductor characteristics, it may be maintained in a turned-on state by the reference voltage VREF (see FIG. 7) of the second channel bias portion CHB2. That is, the second non-design channel portion CHOD2 may not switch according to the reset control signal GR (see FIG. 7) of the reset control line GRL.

Accordingly, because malfunction of the light emitting pixel driver EPD due to the second non-design channel portion CHOD2 may be prevented or reduced, the display quality of the display device 100 may be relatively improved without significantly changing the arrangement of the lines.

The electronic device 10 according to some embodiments may include the display device 100 described above.

Additionally, the electronic device 10 according to some embodiments may further include a module or device having other additional functions in addition to the display device 100.

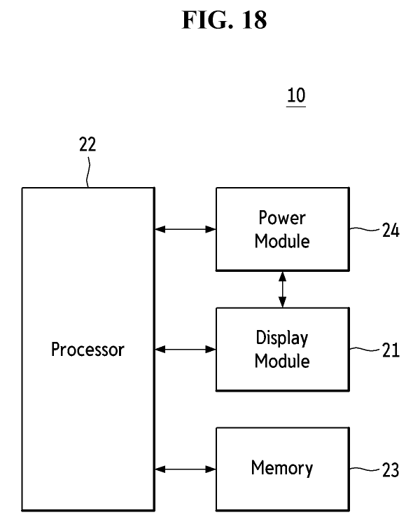

FIG. 18 is a block diagram of an electronic device according to some embodiments.

Referring to FIG. 18, the electronic device 10 according to some embodiments may include a display module 21, a processor 22, a memory 23, and a power module 24.

The display module 21 may include the display device 100 for displaying an image.

The processor 22 may include at least one of a central processing unit (CPU), an application processor (AP), a graphic processing unit (GPU), a communication processor (CP), an image signal processor (ISP), or a controller.

The memory 23 may store data information required for the operation of the processor 22 or the display module 21. When the processor 22 executes an application stored in the memory 23, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power required for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device 100 may include the display module 21, and the processor 22, the memory 23, and the power module 24 may be provided in the form of other devices in the electronic device 10 other than the display device 100.

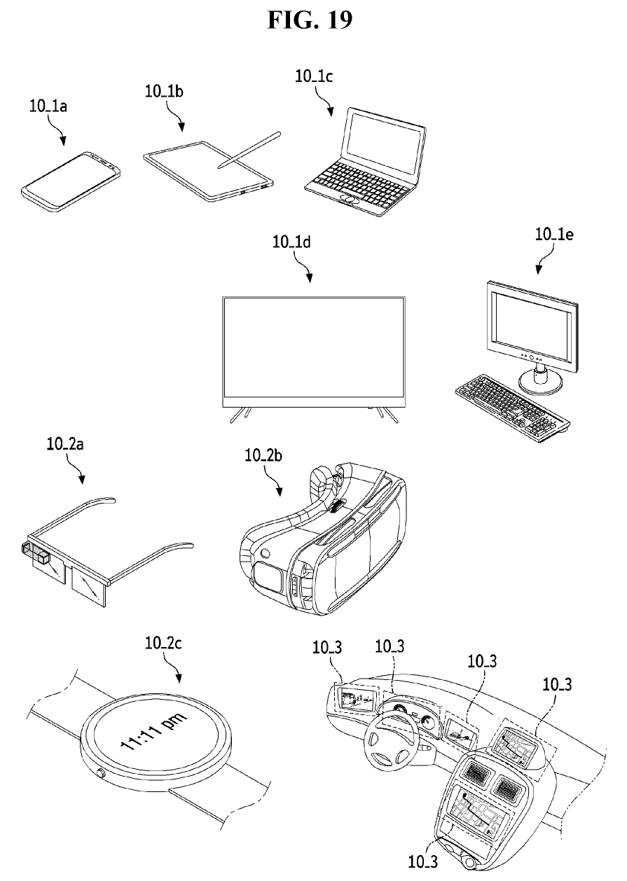

FIG. 19 is schematic views of electronic devices according to various embodiments.

Referring to FIG. 19, the electronic devices 10 according to the embodiments may include not only an image display electronic device such as a smartphone 10_1a, a tablet PC 10_1b, a laptop 10_1c, a TV 10_1d, and a desk monitor 10_1e, but also a wearable electronic device such as smart glasses 10_2a, a head mounted display 10_2b, and a smart watch 10_2c, and a vehicle electronic device 10_3 such as a dashboard of a vehicle, a center fascia, a center information display (CID) of the dashboard, and a room mirror display.

However, the effects of the present disclosure are not restricted to the one set forth herein. The above and other effects of the present disclosure will become more apparent to one of daily skill in the art to which the present disclosure pertains by referencing the claims, and their equivalents.

What is claimed is:

1. A display device comprising:
a substrate comprising a display area in which emission areas are arranged;
a circuit layer on the substrate; and
an element layer on the circuit layer,
wherein the element layer comprises light emitting elements arranged in the emission areas, and
the circuit layer comprises:
light emitting pixel drivers each configured to transmit a driving current to the light emitting elements;
gate lines configured to transmit gate signals to the light emitting pixel drivers;
at least one constant voltage line configured to transmit at least one constant voltage to the light emitting pixel drivers;
at least one channel bias portion electrically connected to the at least one constant voltage line;
a first semiconductor layer on the substrate;
a first interlayer insulating layer on the first semiconductor layer; and
a second semiconductor layer on the first interlayer insulating layer and containing an oxide semiconductor material,
wherein the second semiconductor layer comprises at least one non-design channel portion between some of the gate lines and the at least one channel bias portion in a thickness direction of the substrate.

2. The display device of claim 1, wherein each of the light emitting pixel drivers comprises:
a first transistor configured to generate the driving current;
a second transistor electrically connected between a data line configured to transmit a data signal and a gate electrode of the first transistor;
a third transistor electrically connected between a reference voltage line configured to transmit a reference voltage and the gate electrode of the first transistor;
a fourth transistor electrically connected between an initialization voltage line configured to transmit an initialization voltage and one of the light emitting elements;
a fifth transistor electrically connected between a first power line configured to transmit first power and a first electrode portion of the first transistor; and
a sixth transistor electrically connected between the one light emitting element and a second electrode portion of the first transistor,
wherein the first transistor is in the second semiconductor layer and comprises a channel portion overlapping the gate electrode of the first transistor,
the first electrode portion of the first transistor is in the second semiconductor layer and connected to one side of the channel portion of the first transistor,
the second electrode portion of the first transistor is in the second semiconductor layer and connected to the other side of the channel portion of the first transistor, and
the at least one constant voltage line comprises at least one of the first power line, the reference voltage line, or the initialization voltage line.

3. The display device of claim 2, wherein a gate electrode of the fifth transistor is electrically connected to a first emission control line configured to transmit a first emission control signal,
a gate electrode of the sixth transistor is electrically connected to a second emission control line configured to transmit a second emission control signal different from the first emission control signal,
the sixth transistor comprises a channel portion in the second semiconductor layer and overlapping the gate electrode of the sixth transistor,
a first electrode portion of the sixth transistor is in the second semiconductor layer, connected to one side of the channel portion of the sixth transistor, and electrically connected to the second electrode portion of the first transistor, and
a second electrode portion of the sixth transistor is in the second semiconductor layer, connected to the other side of the channel portion of the sixth transistor, and electrically connected to the one light emitting element.

4. The display device of claim 3, wherein the circuit layer further comprises:
a first gate insulating layer covering the first semiconductor layer;
a first gate conductive layer on the first gate insulating layer;
a second gate insulating layer covering the first gate conductive layer;
a second gate conductive layer on the second gate insulating layer;
a third gate insulating layer covering the second semiconductor layer;
a third gate conductive layer on the third gate insulating layer; and
a first source-drain conductive layer on the second interlayer insulating layer,
wherein the first interlayer insulating layer covers the second gate conductive layer, and
the second interlayer insulating layer covers the third gate conductive layer.

5. The display device of claim 4, wherein the first emission control line is in the first gate conductive layer, and
the first power line comprises:
a power sub-line in the first gate conductive layer and extending in a first direction; and
a power main line in the first source-drain conductive layer and extending in the first direction.

6. The display device of claim 5, wherein the gate lines comprise the first emission control line and the second emission control line,
each of the first emission control line and the second emission control line extends in the first direction,
the first emission control line is between the first transistor and the second emission control line in a second direction intersecting the first direction,
a portion of the power main line extends in the first direction between the first emission control line and the second emission control line in the second direction,
the at least one channel bias portion comprises a first channel bias portion protruding from the power main line and overlapping a portion of the first emission control line, and
the at least one non-design channel portion comprises a first non-design channel portion between a portion of the first emission control line and the first channel bias portion in the thickness direction of the substrate.

7. The display device of claim 2, wherein each of the light emitting pixel drivers further comprises:
a first capacitor electrically connected between the gate electrode of the first transistor and the second electrode portion of the first transistor; and
a second capacitor electrically connected between the first power line and the second electrode portion of the first transistor.

8. The display device of claim 2, wherein each of the light emitting pixel drivers further comprises:
a first capacitor electrically connected between the gate electrode of the first transistor and the second electrode portion of the first transistor;
a second capacitor electrically connected to the second electrode portion of the first transistor; and
a seventh transistor electrically connected between the second capacitor and the reference voltage line,
wherein the seventh transistor is in the second semiconductor layer and comprises a channel portion overlapping a gate electrode of the seventh transistor, and
a first electrode portion and a second electrode portion of the seventh transistor are in the second semiconductor layer.

9. The display device of claim 8, wherein a gate electrode of the third transistor is electrically connected to a reset control line transmitting a reset control signal,
the gate electrode of the seventh transistor is electrically connected to a gate control line transmitting a gate control signal,
each of the reference voltage line, the reset control line, and the gate control line extends in a first direction, and
the reset control line is between the reference voltage line and the gate control line in a second direction intersecting the first direction.

10. The display device of claim 9, wherein the circuit layer further comprises:
a first gate insulating layer covering the first semiconductor layer;
a first gate conductive layer on the first gate insulating layer;
a second gate insulating layer covering the first gate conductive layer;
a second gate conductive layer on the second gate insulating layer;
a third gate insulating layer covering the second semiconductor layer;
a third gate conductive layer on the third gate insulating layer; and
a first source-drain conductive layer on the second interlayer insulating layer,
the reference voltage line comprises:
a reference voltage sub-line in the first semiconductor layer and extending in the first direction; and
a reference voltage main line in the first source-drain conductive layer, extending in the first direction, and overlapping the reference voltage sub-line.

11. The display device of claim 10, wherein the gate lines further comprise the reset control line and the gate control line,
the gate control line is in the third gate conductive layer,
the reset control line is in the first source-drain conductive layer and extends in the first direction,
the at least one channel bias portion comprises a second channel bias portion protruding from the reference voltage sub-line and overlapping a portion of the reset control line, and
the at least one non-design channel portion comprises a second non-design channel portion between a portion of the reset control line and the second channel bias portion in the thickness direction of the substrate.

12. The display device of claim 10, wherein a remaining portion of the first semiconductor layer, excluding a portion intersecting the first emission control line, has conductivity.

13. An electronic device comprising:
a display device configured to display an image;
a memory configured to store an application;
a processor configured to execute the application and to transmit an image data signal and an input control signal to the display device; and
a power module configured to transmit power to the display device,
wherein the display device comprises:
a substrate comprising a display area in which emission areas are arranged;
a circuit layer on the substrate; and
an element layer on the circuit layer,
wherein the element layer comprises light emitting elements arranged in the emission areas, and
the circuit layer comprises:
light emitting pixel drivers each configured to transmit a driving current to the light emitting elements;
a first semiconductor layer on the substrate;
a first interlayer insulating layer on the first semiconductor layer; and
a second semiconductor layer on the first interlayer insulating layer and containing an oxide semiconductor material,
each of the light emitting pixel drivers comprises:
a first transistor configured to generate the driving current;
a second transistor electrically connected between a data line configured to transmit a data signal and a gate electrode of the first transistor;
a third transistor electrically connected between a reference voltage line configured to transmit a reference voltage and the gate electrode of the first transistor;
a fourth transistor electrically connected between an initialization voltage line configured to transmit an initialization voltage and one of the light emitting elements;
a fifth transistor electrically connected between a first power line configured to transmit first power and a first electrode portion of the first transistor; and
a sixth transistor electrically connected between the one light emitting element and a second electrode portion of the first transistor,
wherein the first transistor is in the second semiconductor layer and comprises a channel portion overlapping the gate electrode of the first transistor,
the first electrode portion of the first transistor is in the second semiconductor layer and connected to one side of the channel portion of the first transistor,
the second electrode portion of the first transistor is in the second semiconductor layer and connected to the other side of the channel portion of the first transistor,
a gate electrode of the fifth transistor is electrically connected to a first emission control line configured to transmit a first emission control signal,
a gate electrode of the sixth transistor is electrically connected to a second emission control line configured to transmit a second emission control signal different from the first emission control signal,
the sixth transistor comprises a channel portion in the second semiconductor layer and overlapping the gate electrode of the sixth transistor,
a first electrode portion of the sixth transistor is in the second semiconductor layer, connected to one side of the channel portion of the sixth transistor, and electrically connected to the second electrode portion of the first transistor,
a second electrode portion of the sixth transistor is in the second semiconductor layer, connected to the other side of the channel portion of the sixth transistor, and electrically connected to the one light emitting element,
the second semiconductor layer comprises a first non-design channel portion overlapping a portion of the first emission control line and the first channel bias portion in a thickness direction of the substrate, and
the first channel bias portion is electrically connected to the first power line.

14. The electronic device of claim 13, wherein the circuit layer further comprises:
a first gate insulating layer covering the first semiconductor layer;
a first gate conductive layer on the first gate insulating layer;
a second gate insulating layer covering the first gate conductive layer;
a second gate conductive layer on the second gate insulating layer;
a third gate insulating layer covering the second semiconductor layer;
a third gate conductive layer on the third gate insulating layer; and
a first source-drain conductive layer on the second interlayer insulating layer,
wherein the first interlayer insulating layer covers the second gate conductive layer,
the second interlayer insulating layer covers the third gate conductive layer.
the first emission control line is in the first gate conductive layer,
the gate electrode of the fifth transistor is a portion of the first emission control line,
the second emission control line is in the third gate conductive layer, and
the gate electrode of the sixth transistor is a portion of the second emission control line.

15. The electronic device of claim 14, wherein each of the first emission control line and the second emission control line extends in a first direction, and
the first emission control line is between the first transistor and the second emission control line in a second direction intersecting the first direction.

16. The electronic device of claim 15, wherein the first power line comprises:
a power sub-line in the first gate conductive layer and extending in the first direction; and
a power main line in the first source-drain conductive layer and extending in the first direction,
wherein the first emission control line is between the power sub-line and the power main line in the second direction, and
the first channel bias portion protrudes from the power main line.

17. The electronic device of claim 14, wherein each of the light emitting pixel drivers further comprises:
a first capacitor electrically connected between the gate electrode of the first transistor and the second electrode portion of the first transistor;
a second capacitor electrically connected to the second electrode portion of the first transistor; and
a seventh transistor electrically connected between the second capacitor and the reference voltage line,
wherein the seventh transistor is in the second semiconductor layer and comprises a channel portion overlapping a gate electrode of the seventh transistor, and
a first electrode portion and a second electrode portion of the seventh transistor are in the second semiconductor layer.

18. The electronic device of claim 17, wherein a gate electrode of the third transistor is electrically connected to a reset control line configured to transmit a reset control signal,
the gate electrode of the seventh transistor is electrically connected to a gate control line transmitting a gate control signal,
each of the reference voltage line, the reset control line, and the gate control line extends in a first direction,
the reset control line is between the reference voltage line and the gate control line in a second direction intersecting the first direction,
the second semiconductor layer further comprises a second non-design channel portion overlapping a portion of the reset control line and the second channel bias portion in the thickness direction of the substrate, and
the second channel bias portion is electrically connected to the reference voltage line.

19. The electronic device of claim 18, wherein the reference voltage line comprises:
a reference voltage sub-line in the first semiconductor layer and extending in the first direction; and
a reference voltage main line in the first source-drain conductive layer, extending in the first direction, and overlapping the reference voltage sub-line,
the reset control line is in the first source-drain conductive layer and extends in the first direction, and
the second channel bias portion protrudes from the reference voltage sub-line.

20. The electronic device of claim 19, wherein a remaining portion of the first semiconductor layer, excluding a portion intersecting the first emission control line, has conductivity.
